(19) United States
(12) Patent Application Publication
(10) Pub. No.: US 2025/0393201 A1
(43) Pub. Date: Dec. 25, 2025

(54) SEMICONDUCTOR DEVICE INCLUDING ACTIVE PATTERN

(71) Applicant: Samsung Electronics Co., Ltd., Suwon-si (KR)

(72) Inventors: Hyunjin Lee, Suwon-si (KR); Jiho Park, Suwon-si (KR); Yongkwan Kim, Suwon-si (KR); Huijung Kim, Suwon-si (KR); Heejae Chae, Suwon-si (KR)

(21) Appl. No.: 19/058,005

(22) Filed: Feb. 20, 2025

(30) Foreign Application Priority Data
Jun. 24, 2024 (KR) 10-2024-0082126

(51) Int. Cl. H10B 12/00

(52) U.S. Cl. CPC H10B 12/488; H10B 12/315; H10B 12/482; H10B 12/05

(57) ABSTRACT

A semiconductor device includes a bit line structure, a back gate structure extending on the bit line structure in a first horizontal direction, the back gate structure including a back gate electrode and an upper capping layer on the back gate electrode, a word line structure disposed on the bit line structure, the word line structure including a word line and a gate dielectric layer covering a side surface of the word line, an active pattern disposed on the bit line structure, the active pattern extending in a vertical direction between the back gate structure and the word line structure, and a contact pattern on the active pattern. The upper capping layer includes a seam extending in the first horizontal direction.

### CROSS-REFERENCE TO RELATED APPLICATION(S)

This application claims benefit of priority to Korean Patent Application No. 10-2024-0082126 filed on Jun. 24, 2024 in the Korean Intellectual Property Office, the disclosure of which is incorporated herein by reference in its entirety.

### BACKGROUND

The present inventive concept relates to a semiconductor device including an active pattern.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine separation distance.

### SUMMARY

An aspect of the present inventive concept provides a semiconductor device including an active pattern disposed between a bit line structure and a contact pattern.

According to an aspect of the present inventive concept, there is provided a semiconductor device including a bit line structure, a back gate structure extending on the bit line structure in a first horizontal direction, the back gate structure including a back gate electrode and an upper capping layer on the back gate electrode, a word line structure disposed on the bit line structure, the word line structure including a word line and a gate dielectric layer covering a side surface of the word line, an active pattern disposed on the bit line structure, the active pattern extending in a vertical direction between the back gate structure and the word line structure, and a contact pattern on the active pattern. The upper capping layer may include a seam extending in the first horizontal direction.

According to another aspect of the present inventive concept, there is provided a semiconductor device including a bit line structure on a cell array region, a back gate structure extending from the cell array region to an interface region, on the bit line structure, the back gate structure including a back gate electrode and an upper capping layer on the back gate electrode, a word line structure disposed on the bit line structure, the word line structure extending from the cell array region to the interface region, the word line structure including a word line and a gate dielectric layer covering a side surface of the word line, an active pattern disposed on the bit line structure, on the cell array region, the active pattern extending in a vertical direction between the back gate structure and the word line structure, and a contact pattern on the active pattern. The upper capping layer may include a seam extending from the cell array region to the interface region.

According to another aspect of the present inventive concept, there is provided a semiconductor device including a bit line structure, a back gate structure extending on the bit line structure in a first horizontal direction, the back gate structure including a back gate electrode and an upper capping layer on the back gate electrode, a word line structure disposed on the bit line structure, the word line structure including a word line and a gate dielectric layer covering a side surface of the word line, an active pattern disposed on the bit line structure, the active pattern extending in a vertical direction between the back gate structure and the word line structure, a contact pattern on the active pattern, and an information storage structure on the contact pattern. In a plan view, at least two side surfaces of the active pattern may be in contact with the gate dielectric layer. The upper capping layer may include a seam extending in the first horizontal direction. A lower end and an upper end of the seam may be disposed between a lower surface and an upper surface of the upper capping layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor device according to an example embodiment;

FIG. 1B is vertical cross-sectional views of the semiconductor device illustrated in FIG. 1A, taken along line I-I′ and line II-II′ according to example embodiments;

FIG. 2 is a partially enlarged view of the semiconductor device illustrated in FIG. 1A according to example embodiments;

FIGS. 3 to 6 are plan views of semiconductor devices according to example embodiments;

FIG. 7 is a plan view of a semiconductor device according to an example embodiment;

FIG. 8 is vertical cross-sectional views of the semiconductor device illustrated in FIG. 7, taken along lines I-I′ and II-II′ according to example embodiments;

FIG. 9 is a flowchart of a method of manufacturing a semiconductor device according to an example embodiment;

FIGS. 10A to 10C, 11A to 11C, 12A to 12C, 13A, 13B, 14A to 14C, 15A to 15C, 16A to 16C, 17A to 17C, 18A to 18C, 19A to 19C, 20A to 20C, 21A to 21C, 22A to 22C, 23, and 24 are plan views and vertical cross-sectional views of sequential processes in a method of manufacturing a semiconductor device according to example embodiments;

FIG. 25A is a plan view of a semiconductor device according to an example embodiment;

FIG. 25B is vertical cross-sectional views of the semiconductor device illustrated in FIG. 25A, taken along line V-V′ and line VI-VI′ according to example embodiments; and

FIG. 26 is schematic cross-sectional views of an arrangement structure of a back gate electrode and a word line included in a semiconductor device according to example embodiments.

### DETAILED DESCRIPTION

Hereinafter, preferred example embodiments of the present inventive concept will be described with reference to the accompanying drawings as follows.

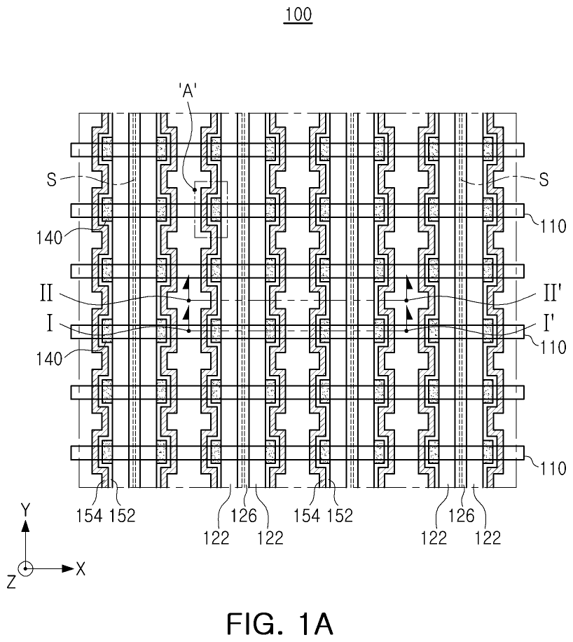

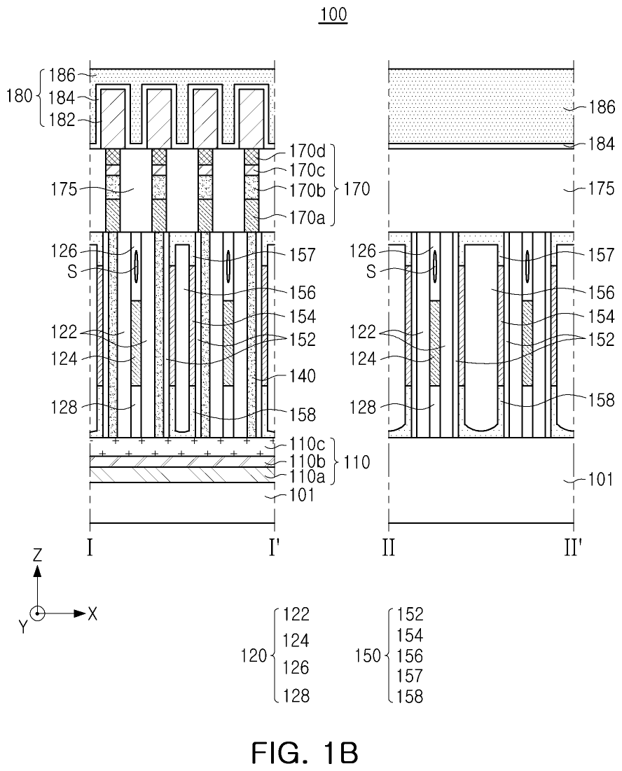

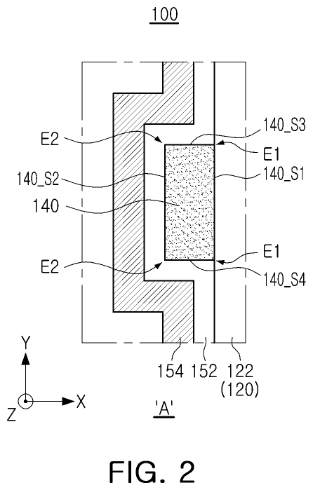

FIG. 1A is a plan view of a semiconductor device according to an example embodiment. FIG. 1B is vertical cross-sectional views of the semiconductor device illustrated in FIG. 1A, taken along line I-I′ and line II-II′ according to example embodiments. FIG. 2 is a partially enlarged view of the semiconductor device illustrated in FIG. 1A according to example embodiments. FIG. 2 may correspond to region “A” of FIG. 1A.

Referring to FIGS. 1A, 1B and 2, a semiconductor device 100 according to an example embodiment of the present inventive concept may include a lower insulating layer 101, a bit line structure 110, a back gate structure 120, an active pattern 140, a word line structure 150, a contact pattern 170, and an information storage structure 180.

The semiconductor device 100 may include a vertical channel transistor including an active pattern 140, a bit line structure 110 electrically connected to the active pattern 140, and word lines 154 disposed on at least one side surface of the active pattern 140.

The semiconductor device 100 may be applied to, for example, a cell array of a dynamic random access memory (DRAM), but the present invention is not limited thereto.

The lower insulating layer 101 may include an insulating material such as silicon oxide, silicon nitride, silicon oxynitride (SiON), or silicon carbon nitride (SiCN).

The bit line structure 110 may extend on the lower insulating layer 101 in an X-direction.

In an example embodiment, the bit line structure 110 may be buried in the lower insulating layer 101. The bit line structure 110 may be electrically connected to the active pattern 140. A plurality of bit line structures 110 may be provided, and the plurality of bit line structures 110 may be spaced apart from each other in a Y-direction, and may extend to be parallel to each other.

The bit line structure 110 may include doped polysilicon, a metal, a conductive metal nitride, a metal-semiconductor compound, a conductive metal oxide, graphene, carbon nanotubes, or combinations thereof. For example, at least one of the bit line structures 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof. In an example embodiment, the bit line structure 110 may include a first conductive pattern 110a, a second conductive pattern 110b, and a third conductive pattern 110c, sequentially stacked on the lower insulating layer 101. The first conductive pattern 110a may include, for example, a metal material such as titanium (Ti), tantalum (Ta), tungsten (W), and aluminum (Al), the second conductive pattern 110b may include, for example, a metal nitride such as titanium nitride (TiN) or a silicide material such as titanium silicide (TiSi), and the third conductive pattern 110c may include a semiconductor material such as polycrystalline silicon. The third conductive pattern 110c may be a layer doped with impurities. However, in some example embodiments, a material of layers of the bit line structure 110, the number of the layers, and a thickness of each of the layers included in the bit line structure 110 may be changed in various manners.

In an example embodiment, the semiconductor device 100 may further include shielding patterns disposed in the lower insulating layer 101, the shielding patterns extending in the X-direction, the shielding patterns spaced apart from each other in the Y-direction. For example, the shielding patterns may be disposed alternately with the bit line structures 110 in the Y-direction. A lower surface of the shielding pattern may be positioned on a level, higher than that of a lower surface of the lower insulating layer 101, and an upper surface of the shielding pattern may be positioned on a level, lower than that of an upper surface of the bit line structure 110. The shielding patterns may reduce capacitance between the bit line structures 110.

The shielding pattern may include doped polysilicon, a metal, a conductive metal nitride, a metal-semiconductor compound, a conductive metal oxide, graphene, carbon nanotubes, or combinations thereof.

The back gate structures 120 may intersect the bit line structures 110. For example, the back gate structures 120 may extend in the Y-direction, and may be spaced apart from each other in the X-direction.

The back gate structure 120 may include a back gate dielectric layer 122, a back gate electrode 124, an upper capping layer 126, and a lower capping layer 128. The back gate electrodes 124 may extend in the Y-direction, and may be spaced apart from each other in the X-direction. The back gate electrode 124 may serve to remove charges trapped in the active pattern 140. The active pattern 140 may be a floating body, and the back gate electrode 124 may be a structure to complement the floating active pattern 140 to prevent or minimize degradation in performance of the semiconductor device 100 caused by a floating body effect of the active pattern 140.

The back gate electrode 124 may include doped polysilicon, a metal, a conductive metal nitride, a metal-semiconductor compound, a conductive metal oxide, graphene, carbon nanotubes, or combinations thereof. For example, the back gate electrode 124 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present invention is not limited thereto. The back gate electrode 124 may be formed of a single layer or multiple layers, formed of the above-described materials.

The back gate dielectric layers 122 may extend in the Y-direction along opposite side surfaces of the back gate electrodes 124. The back gate dielectric layers 122 may cover the opposite side surfaces of the back gate electrodes 124. A vertical length of the back gate dielectric layer 122 may be greater than a vertical length of the back gate electrode 124. For example, an upper surface of the back gate dielectric layer 122 may be positioned on a level, higher than that of an upper surface of the back gate electrode 124, and a lower surface of the back gate dielectric layer 122 may be positioned on a level, lower than that of a lower surface of the back gate electrode 124. In an example embodiment, the lower surface of the back gate dielectric layer 122 may be in contact with the third conductive pattern 110c. Each of the back gate dielectric layers 122 may include at least one of silicon oxide and a high-κ dielectric.

The upper capping layer 126 may be disposed on the back gate electrode 124. Side surfaces of the upper capping layer 126 may be in contact with the back gate dielectric layer 122, and an upper surface of the upper capping layer 126 may be coplanar with upper surfaces of the back gate dielectric layers 122. The upper capping layer 126 may include silicon oxide, silicon nitride, silicon oxynitride, silicon carbon nitride, a low-κ dielectric, or combinations thereof.

In an example embodiment, the upper capping layer 126 may include a seam S therein. An upper end of the seam S may be lower than an upper surface of the upper capping layer 126, and a lower end of the seam S may be higher than a lower surface of the upper capping layer 126. The seam S may be defined as a cavity formed in the upper capping layer 126. In an example embodiment, as illustrated in FIG. 1A, the seam S may continuously extend in the Y-direction in the upper capping layer 126. For example, a seam S in a cross-sectional view taken along line I-I′ illustrated in FIG. 1B may communicate with a seam S in a cross-sectional view taken along line II-II′ illustrated in FIG. 1B. At least portions of the seam S may be positioned on the same vertical level, and may overlap each other in the Y-direction.

The lower capping layer 128 may be disposed below the back gate electrode 124. Side surfaces of the lower capping layer 128 may be in contact with the back gate dielectric layer 122, and a lower surface of the lower capping layer 128 may be coplanar with lower surfaces of the back gate dielectric layers 122. The lower capping layer 128 may include silicon oxide, silicon nitride, silicon oxynitride, silicon carbon nitride, a low-κ dielectric, or combinations thereof.

In an example embodiment, the lower capping layer 128 may include a seam therein. An upper end of the seam may be lower than an upper surface of the lower capping layer 128, and a lower end of the seam may be higher than a lower surface of the lower capping layer 128. In an example embodiment, the seam may continuously extend in the Y-direction in the lower capping layer 128.

The active pattern 140 may be disposed on the bit line structure 110, and may extend in a vertical direction (Z-direction). In a plan view, the active patterns 140 may be disposed on opposite side surfaces of the back gate structures 120. For example, the active patterns 140 may be disposed between the back gate structure 120 and the word line structure 150, adjacent to each other. The active patterns 140 may be spaced apart from each other in the X-direction and the Y-direction. An upper surface of the active pattern 140 may be coplanar with an upper surface of the back gate structure 120. A lower surface of the active pattern 140 may be in contact with the third conductive pattern 110c. It is illustrated that the lower surface of the active pattern 140 is disposed on a level, the same as that of the lower surface of the back gate dielectric layer 122, but the present invention is not limited thereto. In an example embodiment, the lower surface of the active pattern 140 may be positioned on a level, lower than that of the lower surface of the back gate dielectric layer 122.

Each of the active patterns 140 may include a first source/drain region in contact with the bit line structure 110, a second source/drain region in contact with the contact pattern 170, and a channel region between the first source/drain region and the second source/drain region. In an example embodiment, the first and second source/drain regions may have an N-type conductivity. For example, the first and second source/drain regions may be doped with a relatively high concentration of N-type impurities, and the channel region may be doped with a relatively low concentration of P-type impurities.

Referring further to FIG. 2, in a plan view, the active pattern 140 may be in contact with the back gate dielectric layer 122 of the back gate structure 120, and may be in contact with the gate dielectric layer 152 of the word line structure 150. For example, the active pattern 140 may include a first side surface 140_S1 in contact with the back gate dielectric layer 122, and a second side surface 140_S2 in contact with the gate dielectric layer 152. The first side surface 140_S1 and the second side surface 140_S2 may be perpendicular to the X-direction.

In an example embodiment, the active pattern 140 and the word line 154 may have a tri-gate structure. For example, in a plan view, the active pattern 140 may have three side surfaces opposing the word line 154. For example, in a plan view, the active pattern 140 may have a third side surface 140_S3 and a fourth side surface 140_S4 in contact with the gate dielectric layer 152, the third side surface 140_S3 and the fourth side surface 140_S4 perpendicular to the Y-direction. The fourth side surface 140_S4 may be a surface opposite to the third side surface 140_S3. The second side surface 140_S2 of the active pattern 140 may oppose the word line 154, and at least a portion of the third side surface 140_S3 and at least a portion of the fourth side surface 140_S4 may oppose the word line 154. The active pattern 140 and the word line 154 have a tri-gate structure, thereby reducing leakage current and reducing a short channel effect.

The active pattern 140 may include two first edge portions E1 adjacent to the back gate structure 120, and two second edge portions E2 adjacent to the word line structure 150. The first edge portions E1 may refer to portions between the first side surface 140_S1 and the third side surface 140_S3, and between the first side surface 140_S1 and the fourth side surface 140_S4. The second edge portions E2 may refer to portions between the second side surface 140_S2 and the third side surface 140_S3, and between the second side surface 140_S2 and the fourth side surface 140_S4. In an example embodiment, in a plan view, the first edge portions E1 and the second edge portions E2 may be angled. For example, the first edge portions E1 and the second edge portions E2 may be right-angled, but the present invention is not limited thereto.

In an example embodiment, the active patterns 140 may include a single crystal semiconductor material. The single crystal semiconductor material may include a group IV semiconductor, a group III-V compound semiconductor, or a group II-VI compound semiconductor, for example, a single crystal semiconductor including at least one of silicon, silicon carbide, germanium, or silicon-germanium.

However, in some example embodiments, the active patterns 140 may include at least one of a polycrystalline semiconductor material layer, an oxide semiconductor material layer (or, oxide semiconductor layer) such as indium gallium zinc oxide (IGZO), and a two-dimensional (2D) material layer such as MoS₂.

The oxide semiconductor layer may be indium gallium zinc oxide (IGZO). However, the present invention is not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxide (ZnON), manganese zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The two-dimensional material layer may include at least one of a transition metal dichalcogenide (TMD) material layer, a black phosphorous material layer, and a hexagonal boron-nitride (hBN) material layer, which may have semiconductor properties. For example, the 2D material layer may include at least one of BiOSe, Crl, WSe2, MoS2, TaS, WS, SnSe, ReS, β-SnTe, MnO, AsS, P (black), InSe, h-BN, GaSe, GaN, SrTiO, MXene, and a Janus 2D material, which may form a 2D material.

The word line structures 150 may intersect the bit line structures 110. For example, the word line structures 150 may extend in the Y-direction, and may be spaced apart from each other in the X-direction. The word line structures 150 and the back gate structure 120 may be alternately disposed in the X-direction.

The word line structure 150 may include a gate dielectric layer 152, a word line 154, a gap-filling insulating layer 156, a first gate capping layer 157, and a second gate capping layer 158. In the word line structure 150, two word lines 154, spaced apart from each other in the X-direction, may be disposed. The word lines 154 may be disposed on the bit line structure 110, and may be disposed on opposite side surfaces of the back gate structures 120. The word lines 154 may be spaced apart from each other in the X-direction. In a plan view, the word line 154 may surround at least a portion of the active patterns 140, and the active patterns 140 may be disposed between the back gate structures 120 and the word line 154. The word line 154 may be referred to as a “gate electrode” or a “front gate electrode.”

The word line 154 may include doped polysilicon, a metal, a conductive metal nitride, a metal-semiconductor compound, a conductive metal oxide, graphene, carbon nanotubes, or combinations thereof. For example, the word line 154 may be formed of doped polysilicon, Al, Cu, Ti, Ta, Ru, W, Mo, Pt, Ni, Co, TiN, TaN, WN, NbN, TiAl, TiAIN, TiSi, TiN, TaSi, TaSiN, RuTiN, NiSi, CoSi, IrOₓ, RuOₓ, graphene, carbon nanotubes, or combinations thereof, but the present invention is not limited thereto. The word line 154 may be formed of a single layer or multiple layers, formed of the above-described materials. In an example embodiment, the word line 154 may be formed of a material the same as that of the back gate electrode 124, but the present invention is not limited thereto, and may include other materials than the material of the back gate.

FIG. 1 illustrates that two word lines 154 are disposed on opposite sides of one back gate electrode 124, but the present invention is not limited thereto. In an example embodiment, the back gate electrodes 124 may be omitted. In an example embodiment, the back gate structure 120 may be replaced with the word line structure 150. For example, in a plan view, the semiconductor device 100 may have a double gate structure in which the word lines 154 are disposed on opposite sides of the active pattern 140.

The gate dielectric layer 152 may extend in the Y-direction along a side surface of the word line 154. A vertical length of the gate dielectric layer 152 may be greater than a vertical length of the word line 154. For example, an upper surface of the gate dielectric layer 152 may be positioned on a level, higher than that of an upper surface of the word line 154, and a lower surface of the gate dielectric layer 152 may be positioned on a level, lower than that of a lower surface of the word line 154. In an example embodiment, the lower surface of the gate dielectric layer 152 may be in contact with the third conductive pattern 110c.

In an example, each of the gate dielectric layers 152 may be a tunnel dielectric layer, not including an information storage layer. For example, each of the gate dielectric layers 152 may include at least one of silicon oxide and a high-κ dielectric. The high-κ dielectric may include metal oxide or metal oxynitride. For example, the high-κ dielectric may be formed of HfO₂, HfSiO, HfSiON, HfTaO, HfTiO, HfZrO, ZrO₂, Al₂O₃, or combinations thereof, but the present invention is not limited thereto. Each of the gate dielectric layers 152 may be formed of a single layer or multiple layers, formed of the above-described materials.

In another example, each of the gate dielectric layers 152 may include an information storage layer and a dielectric layer. For example, each of the gate dielectric layers 152 may have polarization properties depending on an electric field, and may include a ferroelectric layer that may have remnant polarization caused by a dipole even in the absence of an external electric field. Data may be recorded using such a polarization state in the ferroelectric layer. Accordingly, each of the gate dielectric layers 152 may include a ferroelectric layer, which may be referred to as an information storage layer. The ferroelectric layer, which may be the information storage layer, may include an Hf-based compound, a Zr-based compound, and/or an Hf-Zr-based compound. For example, the Hf-based compound may be a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with an impurity, for example, at least one of C, Si, Mg, Al, Y, N, Ge, Sn, Gd, La, Sc, and Sr. For example, the ferroelectric layer, which may be the information storage layer, may be a material obtained by doping at least one of HfO₂, ZrO₂, and HZrO with at least one of C, Si, Mg, Al, Y, N, Ge, Sn, Gd, La, Sc, and Sr.

In the gate dielectric layers 152, the information storage layer is not limited to the above-described material types, and may include a material capable of storing information.

A gap-filling insulating layer 156 may extend in the Y-direction between the adjacent word lines 154, and may be spaced apart from each other in the X-direction. The gap-filling insulating layer 156 may be in contact with side surfaces of the adjacent word lines 154 facing each other. A vertical length of the gap-filling insulating layer 156 may be greater than a vertical length of the word line 154. For example, an upper surface of the gap-filling insulating layer 156 may be positioned on a level, higher than that of an upper surface of the word line 154, and a lower surface of the gap-filling insulating layer 156 may be positioned on a level, lower than that of a lower surface of the word line 154.

The first gate capping layer 157 may be disposed on the gap-filling insulating layer 156, and may be in contact with upper surfaces of the word lines 154 and the gate dielectric layer 152. The first gate capping layer 157 may be in contact with an upper surface and a side surface of the gap-filling insulating layer 156. An upper surface of the first gate capping layer 157 may be coplanar with an upper surface of the active pattern 140 and an upper surface of the back gate structure 120.

The second gate capping layer 158 may be disposed below the gap-filling insulating layer 156, and may be in contact with lower surfaces of the word lines 154 and the gate dielectric layer 152. The second gate capping layer 158 may be in contact with lower and side surfaces of the gap-filling insulating layer 156. A lower surface of the second gate capping layer 158 may be coplanar with a lower surface of the active pattern 140 and a lower surface of the back gate structure 120. The structures of the gap-filling insulating layer 156, the first gate capping layer 157, and the second gate capping layer 158 of FIG. 1B may be exemplary, and are not limited thereto.

The gap-filling insulating layer 156, the first gate capping layer 157, and the second gate capping layer 158 may include silicon oxide, silicon nitride, silicon oxynitride, silicon carbon nitride, a low-κ dielectric, or combinations thereof. For example, the gap-filling insulating layer 156 may include silicon oxide, and the first gate capping layer 157 and the second gate capping layer 158 may include silicon nitride.

The contact patterns 170 may be disposed on the active patterns 140, and may be electrically connected to the active patterns 140. Lower surfaces of the contact patterns 170 may be in contact with the back gate dielectric layer 122, the active pattern 140, and the gate dielectric layer 152. The contact patterns 170 may electrically connect the active patterns 140 to the information storage structure 180 to each other.

The contact patterns 170 may include a conductive material, for example, doped single crystal silicon, doped polycrystalline silicon, a metal, a conductive metal nitride, a metal-semiconductor compound, a conductive metal oxide, conductive graphene, carbon nanotubes, or combinations thereof. In an example embodiment, the contact patterns 170 may include first to fourth contact layers 170a, 170b, 170c, and 170d, sequentially stacked. For example, the first contact layer 170a may include undoped polycrystalline silicon, the second contact layer 170b may include doped polycrystalline silicon, the third contact layer 170c may include a silicide material, and the fourth contact layer 170d may include a metal. However, in some example embodiments, the number of layers of the contact patterns 170 and a type of material of the layers may be changed in various manners.

The semiconductor device 100 may further include insulating patterns 175, disposed between the contact patterns 170. Each of the insulating patterns 175 may vertically extend to be in contact with at least one of the back gate capping layer 122, the upper capping layer 126, the gate dielectric layer 152, and the first gate capping layer 157. The insulating patterns 175 may spatially separate the contact patterns 170 from each other, and may electrically insulate the contact patterns 170 from each other.

The information storage structures 180 may include first electrodes 182 electrically connected to the contact patterns 170, second electrodes 186 covering the first electrodes 182, and a dielectric layer 184 between the first electrodes 182 and the second electrode 186.

In an example embodiment, the information storage structures 180 may be capacitors storing information in the DRAM. For example, the dielectric layer 184 of the information storage structures 180 may be a capacitor dielectric layer of the DRAM, and the dielectric layer 184 may include a high-κ dielectric, silicon oxide, silicon nitride, silicon oxynitride, or combinations thereof.

In some example embodiments, the information storage structures 180 may be structures that store DRAM and other memory information. For example, the dielectric layer 184 of the information storage structures 180 may be a capacitor dielectric layer of a ferroelectric memory (FeRAM). In this case, the dielectric layer 184 may be a ferroelectric layer capable of recording data using a polarization state. In another embodiment, the dielectric layer 184 may also include a lower dielectric layer including at least one of silicon oxide or a high-k dielectric, and a ferroelectric layer disposed on the lower dielectric layer.

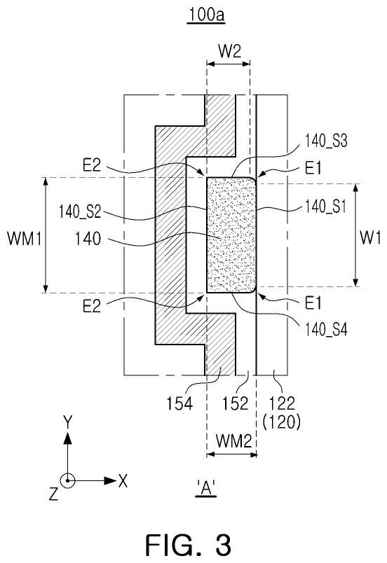

FIGS. 3 to 6 are plan views of semiconductor devices according to example embodiments.

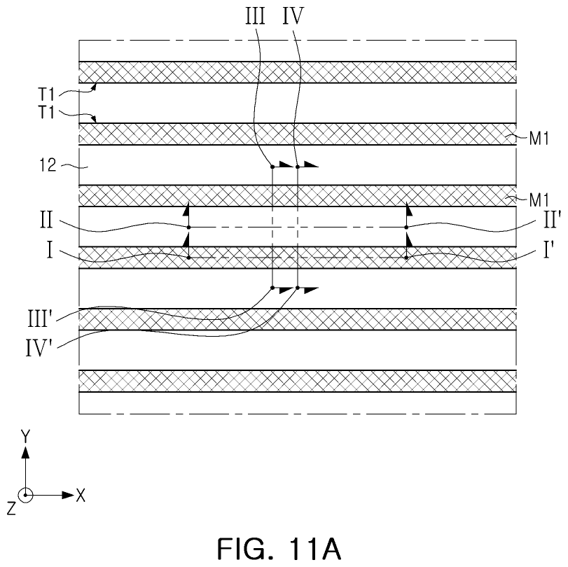

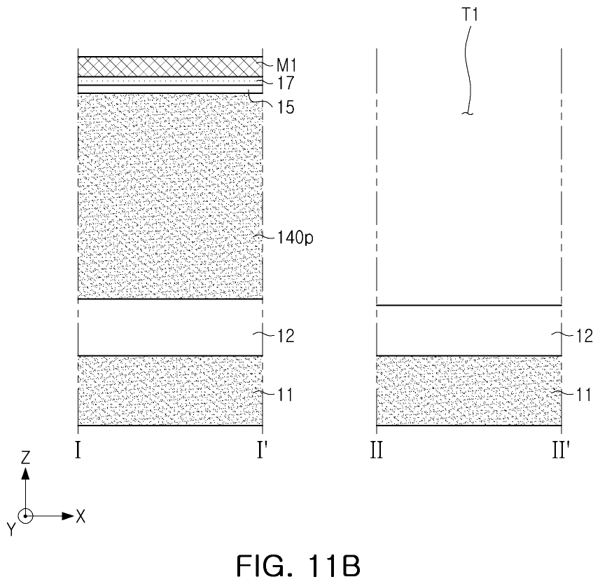

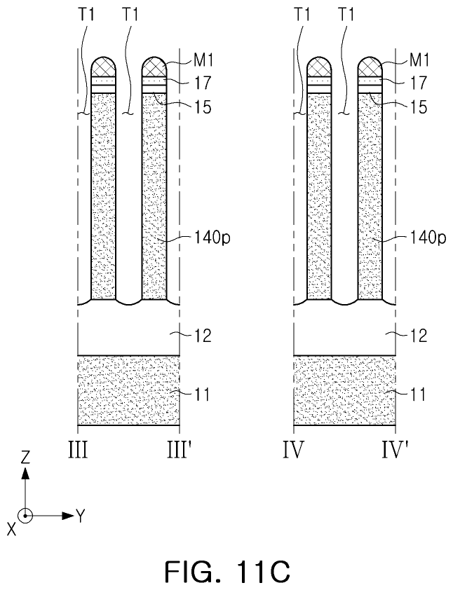

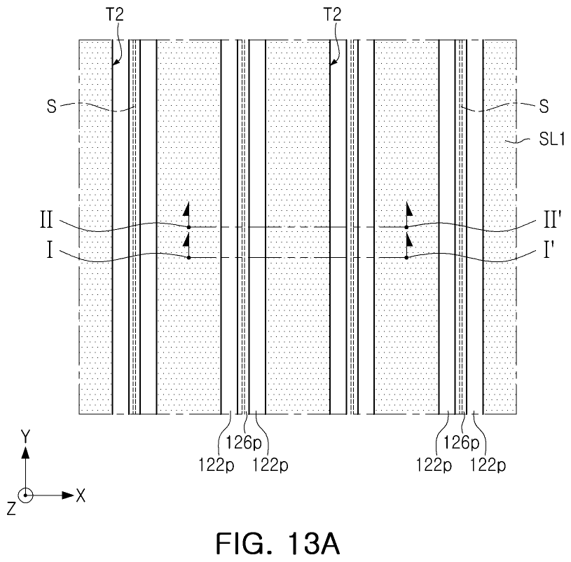

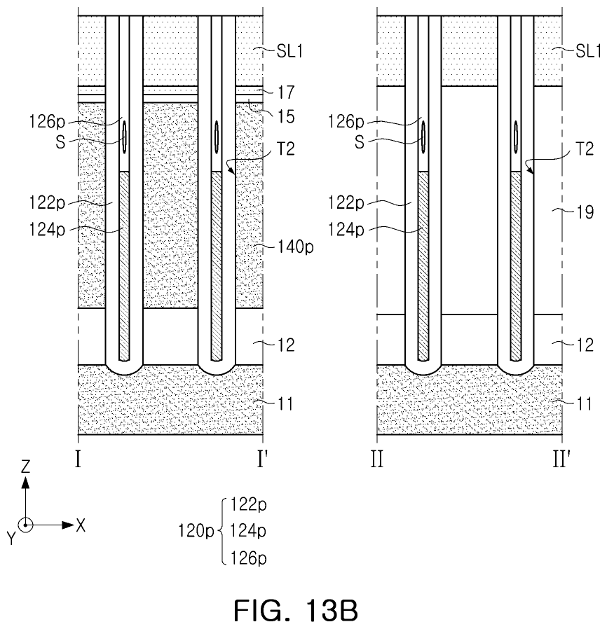

Referring to FIG. 3, a semiconductor device 100a may include an active pattern 140 disposed on a side surface of a back gate structure 120. In an example embodiment, in a plan view, at least one of first edge portions E1 and second edge portions E2 of the active pattern 140 may be rounded. For example, the first edge portions E1 may be rounded. In a process of forming a preliminary active pattern 140p in FIGS. 11A to 11C and/or a process of forming a back gate trench T2 in FIGS. 13A and 13B to be described below, a portion of the preliminary active pattern 140p corresponding to the first edge portions E1 may be etched to be rounded. The second edge portions E2 may be angled.

At least one of the first edge portions E1 and the second edge portions E2 of the active pattern 140 may be rounded, such that the active pattern 140 may have different widths in an X-direction and a Y-direction. For example, a first side surface 140_S1 of the active pattern 140 may have a first width W1 in the Y-direction, and the first width W1 may be less than a maximum width WM1 of the active pattern 140 in the Y-direction. A third side surface 140_S3 or a fourth side surface 140_S4 of the active pattern 140 may have a second width W2 in the X-direction, and the second width W2 may be less than a maximum width WM2 of the active pattern 140 in the X- direction.

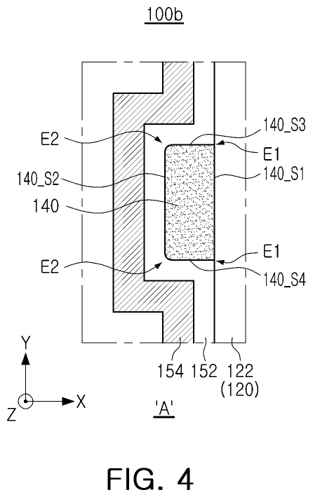

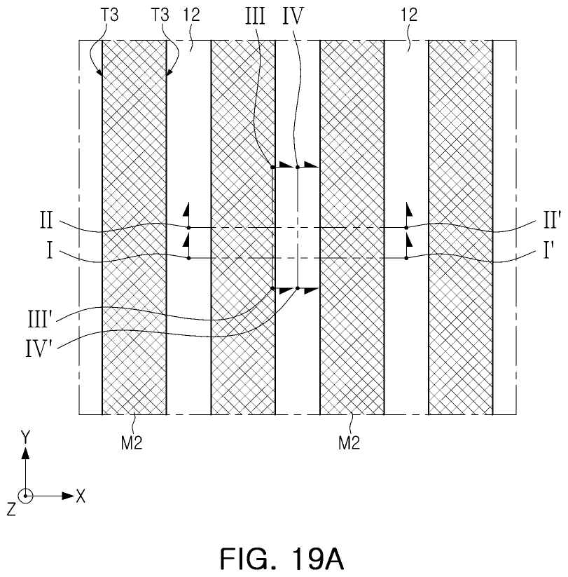

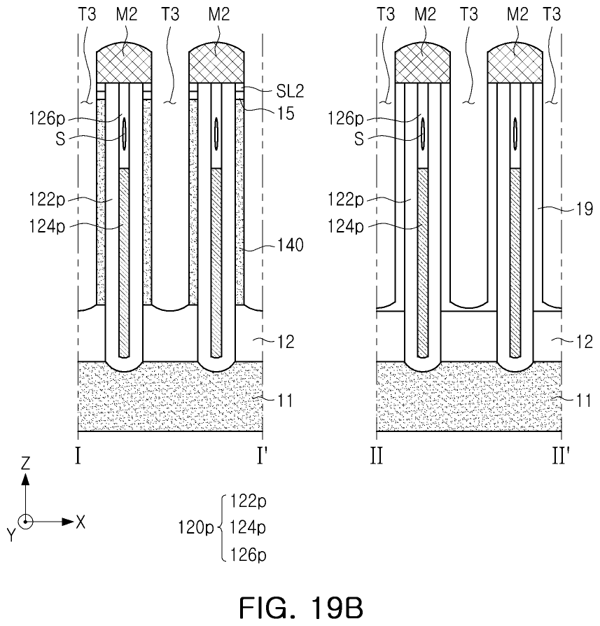

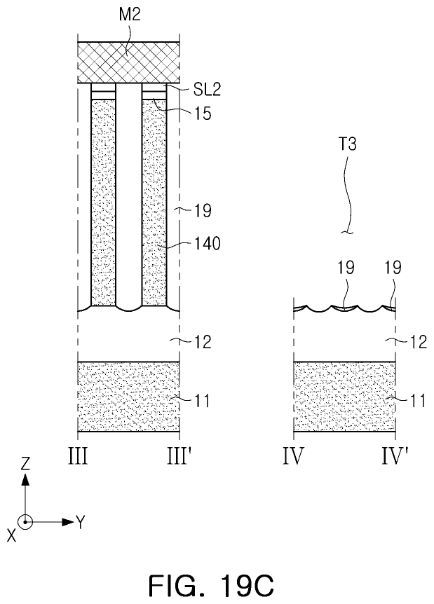

Referring to FIG. 4, a semiconductor device 100b may include an active pattern 140 disposed on a side surface of a back gate structure 120. In an example embodiment, in a plan view, first edge portions E1 may be angled. Second edge portions E2 may be rounded. In a process of forming a preliminary active pattern 140p in FIGS. 11A to 11C and/or a process of forming a gate trench T3 in FIGS. 19A and 19B to be described below, a portion of the preliminary active pattern 140p corresponding to the second edge portions E2 may be etched to be rounded.

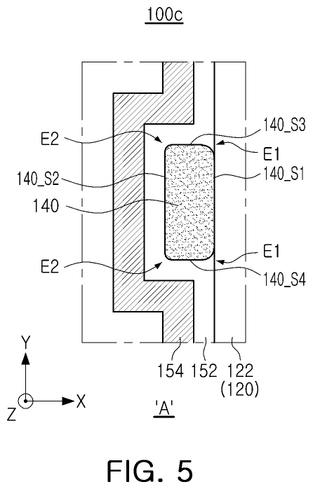

Referring to FIG. 5, a semiconductor device 100c may include an active pattern 140 disposed on a side surface of a back gate structure 120. In an example embodiment, in a plan view, first edge portions E1 and second edge portions E2 of the active pattern 140 may be rounded. As will be described below, the active pattern 140 may be formed using two etching processes, such that the first edge portions E1 may not be the same as the second edge portions E2. A radius of curvature of the first edge portions E1 may be different from a radius of curvature of the second edge portions E2. For example, the radius of curvature of the first edge portions E1 may be greater than the radius of curvature of the second edge portions E2.

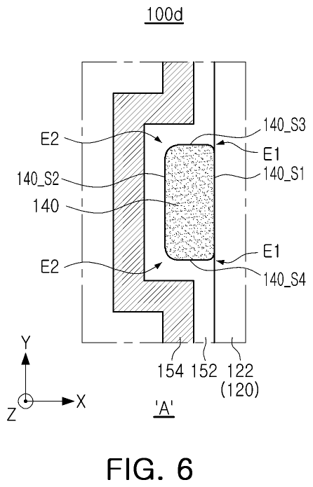

Referring to FIG. 6, a semiconductor device 100d may include an active pattern 140 disposed on a side surface of a back gate structure 120. In an example embodiment, in a plan view, first edge portions E1 and second edge portions E2 of the active pattern 140 may be rounded. As will be described below, the active pattern 140 may be formed using two etching processes, such that the first edge portions E1 may not be the same as the second edge portions E2. A radius of curvature of the first edge portions E1 may be different from a radius of curvature of the second edge portions E2. For example, the radius of curvature of the first edge portions E1 may be less than the radius of curvature of the second edge portions E2.

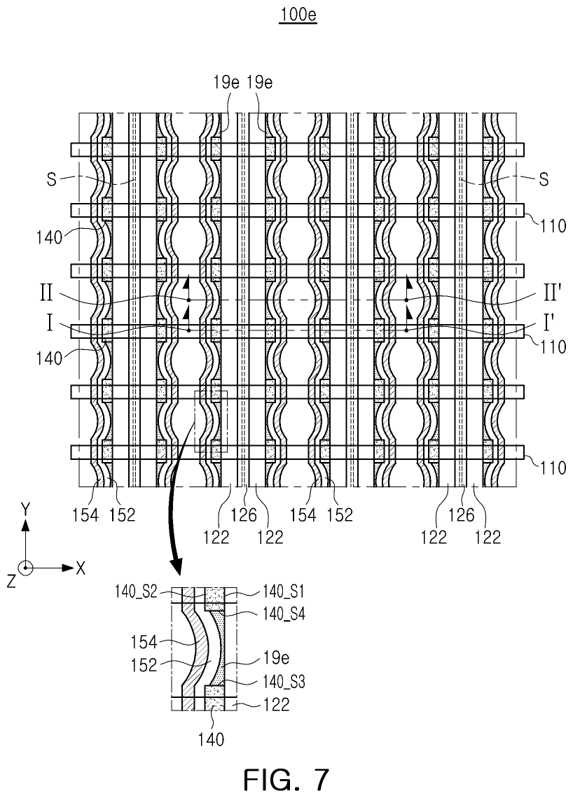

FIG. 7 is a plan view of a semiconductor device according to an example embodiment.

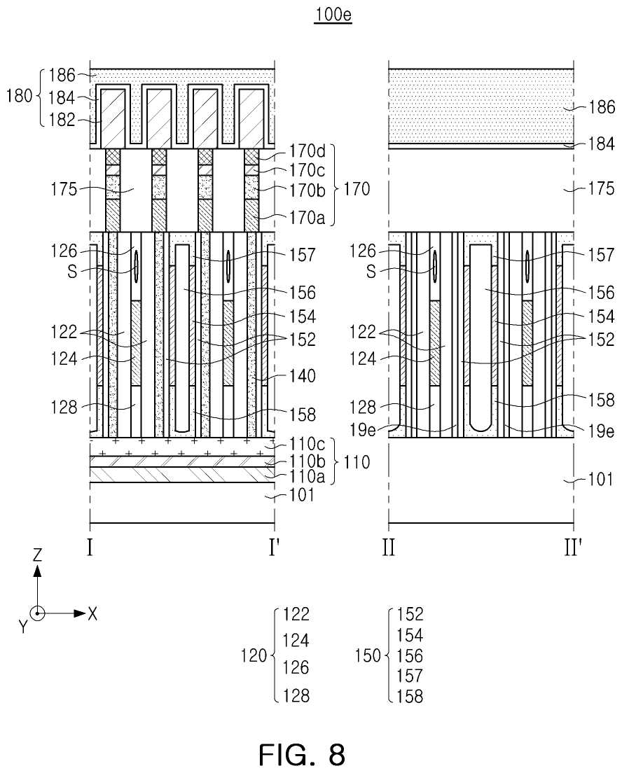

FIG. 8 is vertical cross-sectional views of the semiconductor device illustrated in FIG. 7, taken along lines I-I′ and II-II′ according to example embodiments.

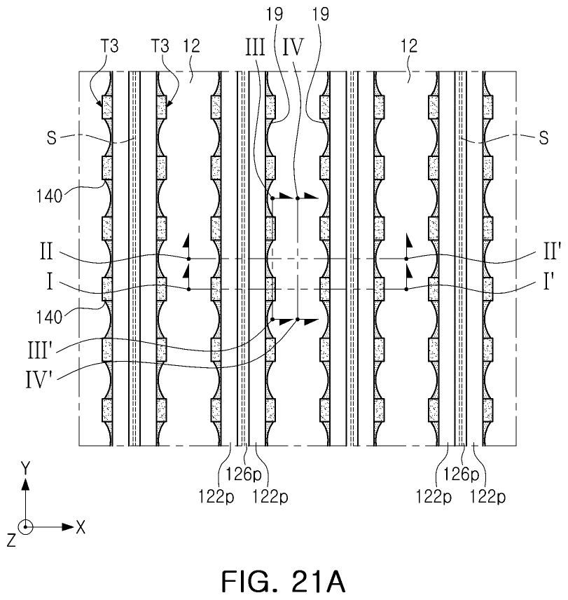

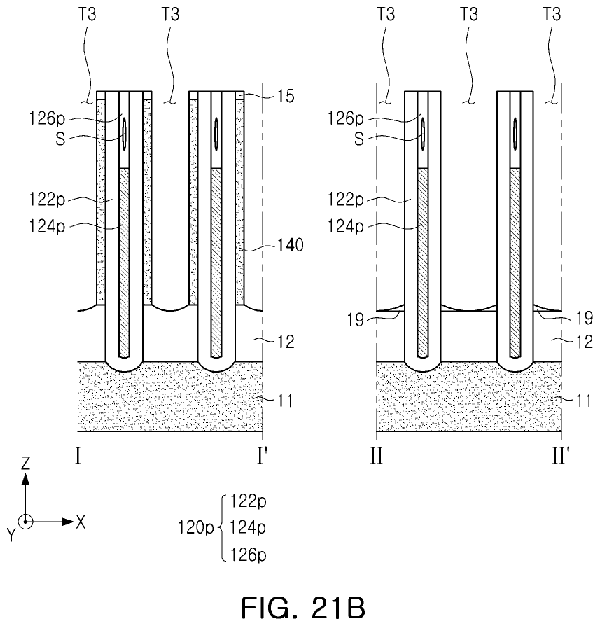

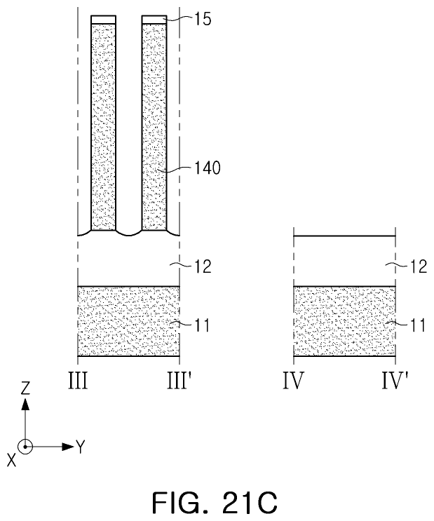

Referring to FIGS. 7 and 8, a semiconductor device 100e may include active patterns 140 disposed on a side surface of a back gate structure 120 and a liner 19e between the active patterns 140. In an etching process described with reference to FIGS. 21A to 21C, an interlayer insulating layer 19 may not be entirely removed, and a remaining interlayer insulating layer 19 that is not removed may be referred to as the liner 19e.

The liner 19e may cover a back gate dielectric layer 122 of the back gate structure 120. For example, the liner 19e may be disposed between the back gate structure 120 and a word line structure 150, and may be in contact with the back gate dielectric layer 122 and a gate dielectric layer 152. In an embodiment, the liner 19e may secure a distance between the back gate structure 120 and the word line structure 150 such that a reliability of the semiconductor device 100e may be improved. The liner 19e may include silicon oxide, silicon nitride, silicon oxynitride, silicon carbon nitride, a low-κ dielectric, or combinations thereof. For example, the liner 19e may include silicon oxide. In an example embodiment, the liner 19e may have a density lower than those of the back gate dielectric layer 122 and the gate dielectric layer 152.

In a plan view, a side surface of the liner 19e may have a curved surface. For example, one side surface of the liner 19e may be in contact with the back gate dielectric layer 122, and may be coplanar with the active pattern 140, and the other side surface, opposite to the one side surface, may be a curved surface. In an example embodiment, the side surfaces of the liner 19e may be flat surfaces, and may be parallel to a side surface of the back gate dielectric layer 122. Each liner 19e may cover a third side surface 140_S3 or a fourth side surface 140_S4 of the active pattern 140, but may not entirely cover the third side surface 140_S3 or the fourth side surface 140_S4. For example, a maximum horizontal width of the liner 19e in an X-direction may be less than a horizontal width of the active pattern 140 in the X-direction. The third side surface 140_S3 and the fourth side surface 140_S4 of the active pattern 140 may be in contact with both the liner 19e and the gate dielectric layer 152.

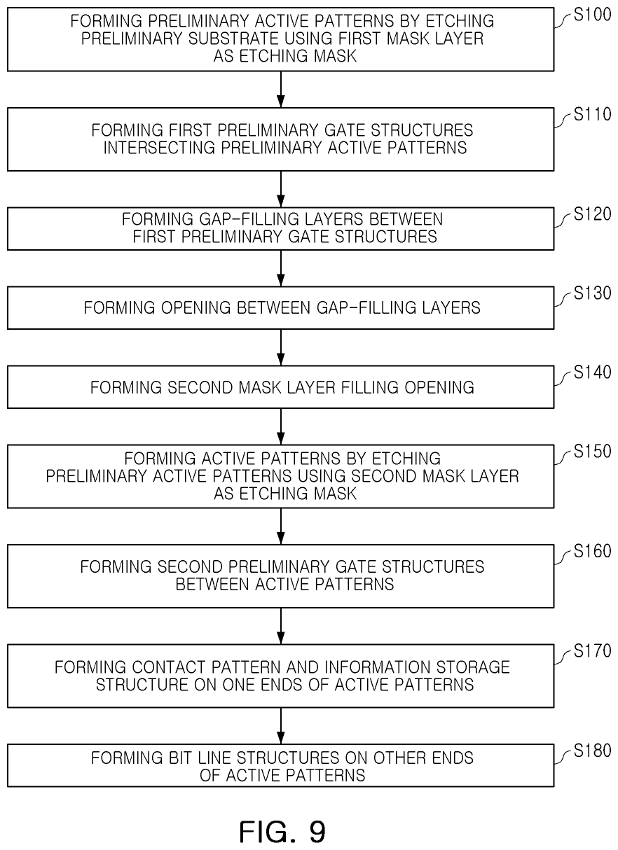

FIG. 9 is a flowchart of a method of manufacturing a semiconductor device according to an example embodiment.

Referring to FIG. 9, a method of manufacturing a semiconductor device according to an example embodiment may include forming preliminary active patterns by etching a preliminary substrate using a first mask layer as an etching mask (S100), forming first preliminary gate structures, intersecting the preliminary active patterns (S110), forming gap-filling layers between the first preliminary gate structures (S120), forming an opening between the gap-filling layers by etching upper portions of the first preliminary gate structures (S130), forming a second mask layer filling the opening (S140), forming active patterns by etching the preliminary active patterns using the second mask layer as an etching mask (S150), forming second preliminary gate structures between the active patterns (S160), forming a contact pattern and an information storage structure on one ends of the active patterns (S170), and forming bit line structures on the other ends of the active patterns (S180).

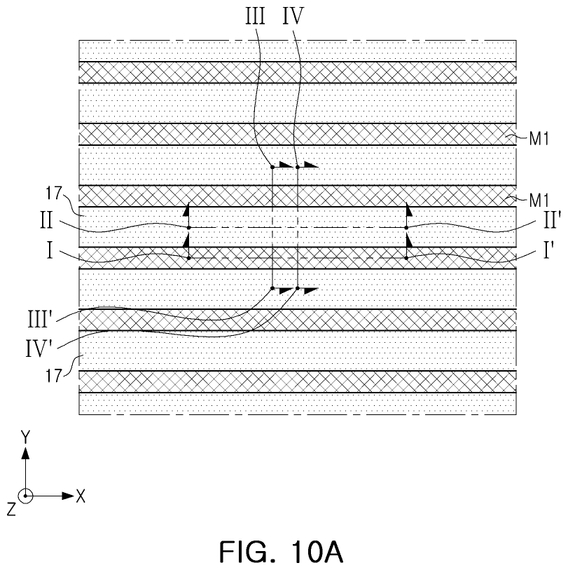

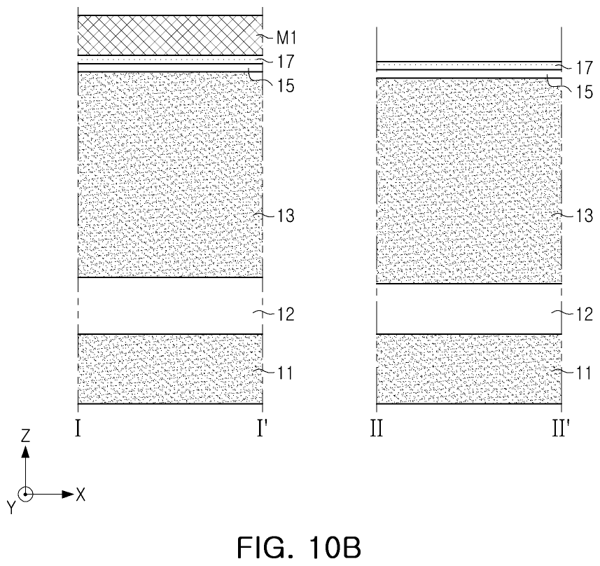

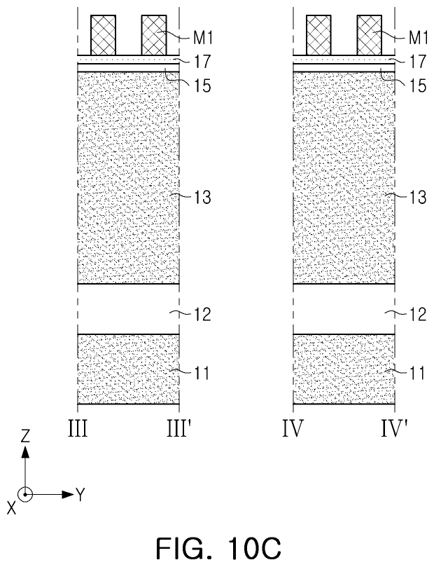

FIGS. 10A to 10C, 11A to 11C, 12A to 12C, 13A, 13B, 14A to 14C, 15A to 15C, 16A to 16C, 17A to 17C, 18A to 18C, 19A to 19C, 20A to 20C, 21A to 21C, 22A to 22C, 23, and 24 are plan views and vertical cross-sectional views of sequential processes in a method of manufacturing a semiconductor device according to example embodiments. Specifically, FIGS. 10A, 11A, 12A, 13A, 14A, 15A, 16A, 17A, 18A, 19A, 20A, 21A, and 22A are plan views corresponding to FIG. 1A. FIGS. 10B, 11B, 12B, 13B, 14B, 15B, 16B, 17B, 18B, 19B, 20B, 21B, 22B, 23 and 24 are vertical cross-sectional views corresponding to FIG. 1B. FIGS. 10C, 11C, 12C, 14C, 15C, 16C, 17C, 18C, 19C, 20C, 21C, and 22C are respectively vertical cross-sectional views of FIGS. 10A, 11A, 12A, 14A, 15A, 16A, 17A, 18A, 19A, 20A, 21A, and 22A, taken along lines III-III′ and IV-IV′.

Referring to FIGS. 10A to 10C, a lower substrate 11, an intermediate layer 12, and a preliminary substrate 13 may be provided. The lower substrate 11, the intermediate layer 12, and the preliminary substrate 13 may be stacked in a vertical direction, and the intermediate layer 12 may be disposed between the lower substrate 11 and the preliminary substrate 13.

In an example embodiment, the lower substrate 11 and the preliminary substrate 13 may be semiconductor material layers, and the intermediate layer 12 may be an insulating layer. For example, the lower substrate 11, the intermediate layer 12, and the preliminary substrate 13 may be a silicon-on-insulator (SOI) substrate, and the lower substrate 11 and the preliminary substrate 13 may include single crystal silicon. In an example embodiment, the lower substrate 11, the intermediate layer 12, and the preliminary substrate 13 may be semiconductor material layers, and the intermediate layer 12 and the preliminary substrate 13 may be formed on the lower substrate 11 using a deposition method or an epitaxial growth method. In an example embodiment, the preliminary substrate 13 may be a bulk silicon substrate, and the lower substrate 11 and the intermediate layer 12 may be omitted.

A first buffer layer 15 and a second buffer layer 17 may be formed on the preliminary substrate 13. Each of the first buffer layer 15 and the second buffer layer 17 may include silicon oxide, silicon nitride, silicon oxynitride, silicon carbon nitride, a low-κ dielectric, or combinations thereof. The first buffer layer 15 may include a material, different from that of the second buffer layer 17. For example, the first buffer layer 15 may include silicon oxide, and the second buffer layer 17 may include silicon nitride. The first buffer layer 15 and the second buffer layer 17 illustrated in FIG. 10B may be exemplary, and are not limited thereto. In an example embodiment, a single buffer layer may be formed on the preliminary substrate 13.

First mask layers M1 may be formed on the second buffer layer 17. The first mask layers M1 may extend in an X-direction, and may be spaced apart from each other in a Y-direction. The first mask layer M1 may include a material having etch selectivity with respect to the second buffer layer 17. In an example embodiment, the first mask layer M1 may include silicon oxide, silicon nitride, silicon oxynitride, silicon carbon nitride, an amorphous carbon layer (ACL), a low-κ dielectric, or combinations thereof. In an example embodiment, the first mask layer M1 may include polysilicon, a metal, a conductive metal nitride, or combinations thereof.

Referring to FIGS. 11A to 11C, preliminary active patterns 140p may be formed by etching the preliminary substrate 13 using the first mask layer M1 as an etching mask (S100 of FIG. 9). For example, the preliminary substrate 13 may be etched using the first mask layer M1 as an etching mask, thereby forming channel trenches T1 in the preliminary substrate 13. The channel trenches T1 may extend in the X-direction, and may be spaced apart from each other in the Y-direction. The preliminary active patterns 140p may be defined by the channel trenches T1. For example, the preliminary active patterns 140p may extend in the X-direction, and may be spaced apart from each other in the Y-direction. The channel trenches T1 may expose side surfaces of the preliminary active patterns 140p and an upper surface of the intermediate layer 12. The first mask layer M1 may be partially etched using an etching process. For example, the preliminary active patterns 140p may be spaced apart from each other in the Y-direction by an etching process using the first mask layer M1 as an etching mask.

In an example embodiment, a doping process may be performed on the preliminary active patterns 140p exposed by the channel trenches T1. For example, a doping process, such as a gas phase doping (GPD) process or a plasma doping (PLAD) process, may be performed to dope N-type impurities or P-type impurities into the preliminary active patterns 140p.

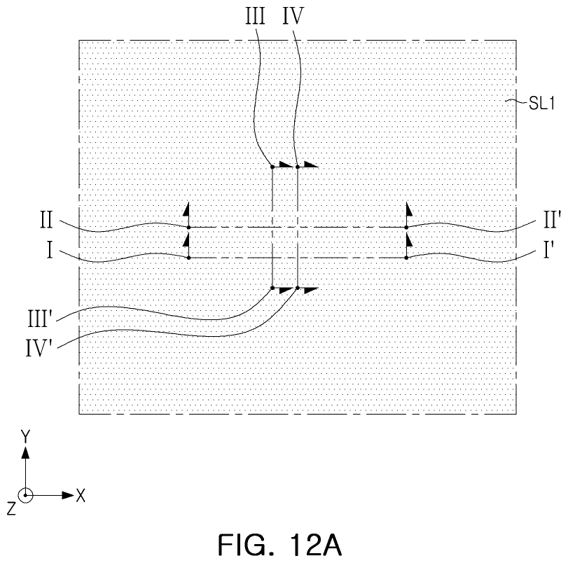

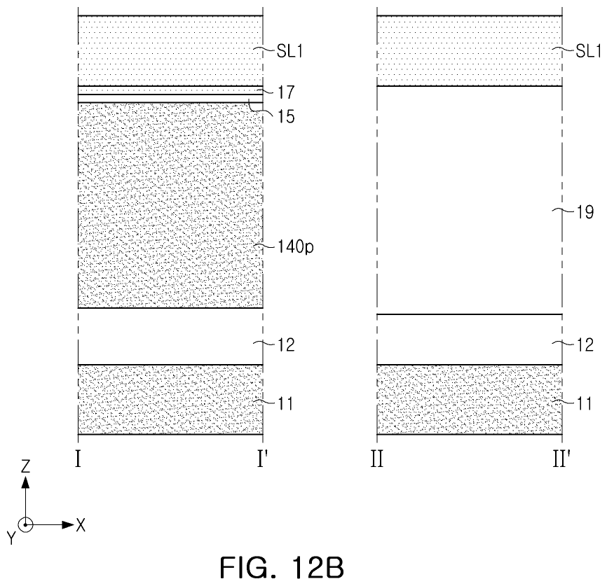

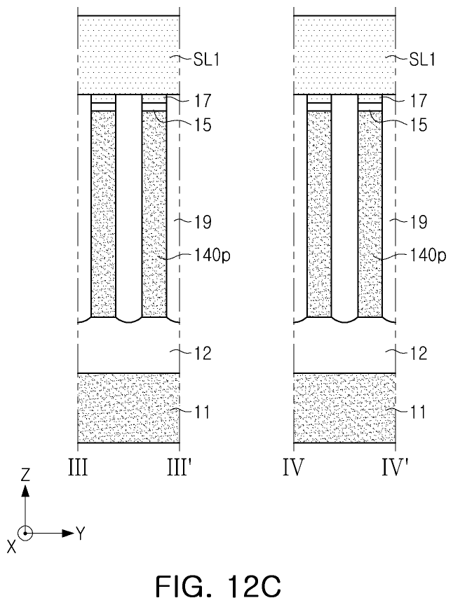

Referring to FIGS. 12A to 12C, interlayer insulating layers 19 may be formed between the preliminary active patterns 140p. For example, after the first mask layer M1 is selectively removed, an insulating material layer may be formed to cover the second buffer layer 17 by filling the channel trenches T1. The insulating material layer may be planarized to expose an upper surface of the second buffer layer 17, thereby forming the interlayer insulating layers 19. For example, the planarization process may be performed using a chemical mechanical polishing (CMP) process. The interlayer insulating layers 19 may be coplanar with the upper surface of the second buffer layer 17. The interlayer insulating layers 19 may extend in the X-direction, and may be spaced apart from each other in the Y-direction.

The interlayer insulating layers 19 may include silicon oxide, silicon nitride, silicon oxynitride, silicon carbon nitride, a low-κ dielectric, or combinations thereof. For example, the interlayer insulating layers 19 may include silicon oxide.

A first sacrificial layer SLI may be formed on the second buffer layer 17 and the interlayer insulating layers 19. The first sacrificial layer SL1 may include silicon oxide, silicon nitride, silicon oxynitride, silicon carbon nitride, a low-κ dielectric, or combinations thereof. The first sacrificial layer SL1 may include a material having etch selectivity with respect to the interlayer insulating layers 19. For example, the first sacrificial layer SL1 may include silicon nitride.

Referring to FIGS. 13A and 13B, first preliminary gate structures 120p, intersecting the preliminary active patterns 140p, may be formed (S110 of FIG. 9). Formation of the first preliminary gate structures 120p may include forming back gate trenches T2 in the preliminary active patterns 140p and filling the back gate trenches T2 with a dielectric material, a conductive material, and an insulating material. For example, the back gate trenches T2 may extend in the Y-direction, and may be spaced apart from each other in the X-direction. The back gate trenches T2 may expose side surfaces of the preliminary active patterns 140p, and may expose inner walls of the intermediate layer 12, the first buffer layer 15, the second buffer layer 17, the interlayer insulating layer 19, and the first sacrificial layer SL1. The back gate trenches T2 may also expose an upper surface of the lower substrate 11.

A dielectric material layer 122p may be deposited on inner walls of the back gate trenches T2, a conductive material layer may be formed on the dielectric material layer 122p, and the back gate electrode layers 124p may be formed by etching the conductive material layer. Preliminary capping layers 126p may be formed on the back gate electrode layers 124p to entirely fill the back gate trenches T2.

In an example embodiment, the preliminary capping layers 126p may be formed using a deposition process, such as a chemical vapor deposition (CVD) process, an atomic layer deposition (ALD) process, or the like, and may be deposited from side surfaces of the dielectric material layer 122p and an upper surface of the back gate electrode layer 124p. In an example embodiment, a seam S may be formed in the preliminary capping layer 126p. The seam S, included in the preliminary capping layer 126p, may continuously extend in the Y-direction. The dielectric material layer 122p, the back gate electrode layer 124p, and the preliminary capping layer 126p may form a first preliminary gate structure 120p. An upper surface of the first preliminary gate structure 120p may be coplanar with an upper surface of the first sacrificial layer SL1.

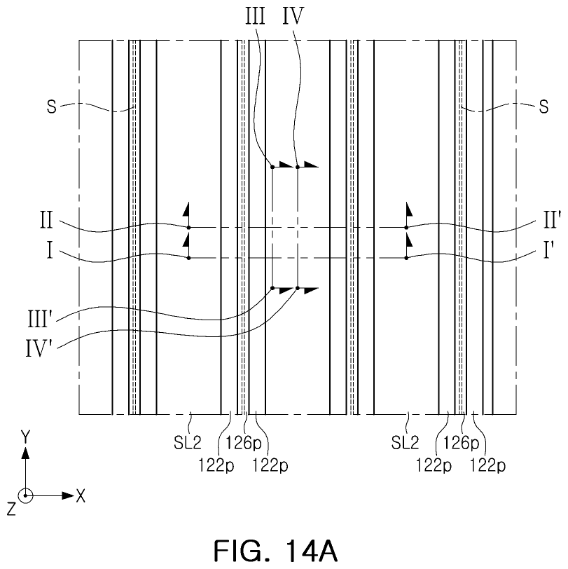

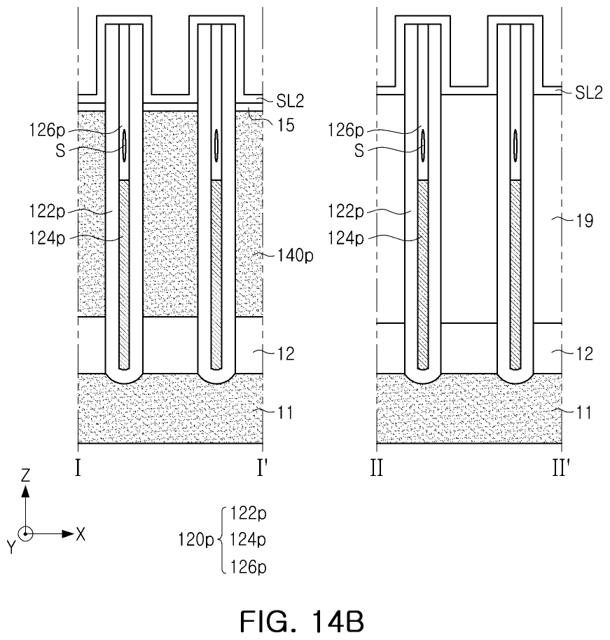

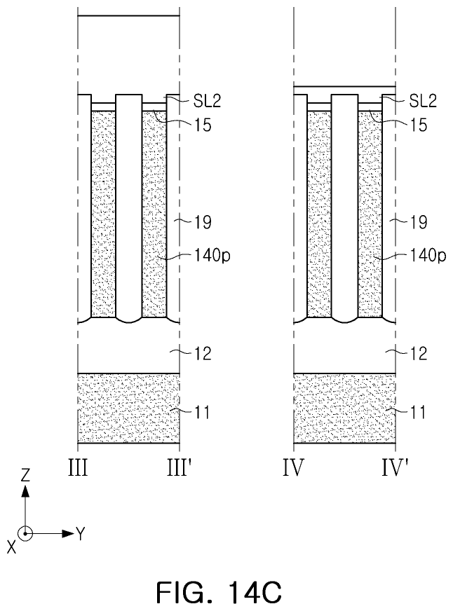

Referring to FIGS. 14A to 14C, the second buffer layer 17 and the first sacrificial layer SL1 may be removed. For example, the second buffer layer 17 and the first sacrificial layer SL1 may be removed using a wet etching process, and the first buffer layer 15 and the interlayer insulating layer 19 having etch selectivity with respect to the second buffer layer 17 may not be etched. A side surface of an upper portion of the first preliminary gate structure 120p may be exposed using the etching process.

A second sacrificial layer SL2 may be formed on the exposed upper portion of the first preliminary gate structure 120p. The second sacrificial layer SL2 may be formed along surfaces of the first buffer layer 15, the interlayer insulating layer 19, and the first preliminary gate structure 120p. The second sacrificial layer SL2 may include silicon oxide, silicon nitride, silicon oxynitride, silicon carbon nitride, a low-κ dielectric, or combinations thereof. For example, the second sacrificial layer SL2 may include silicon oxide.

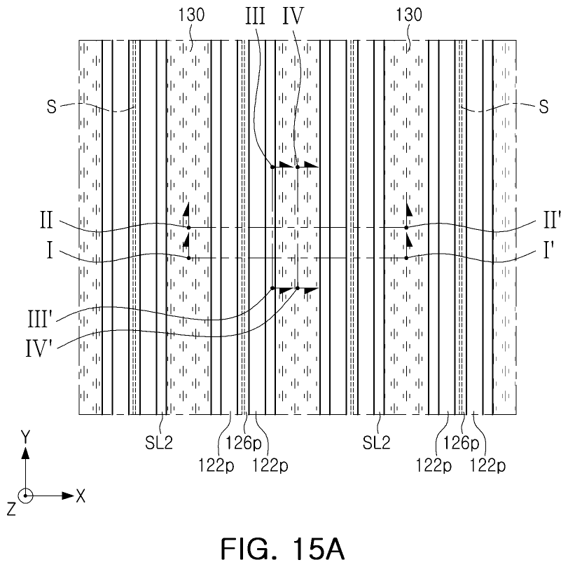

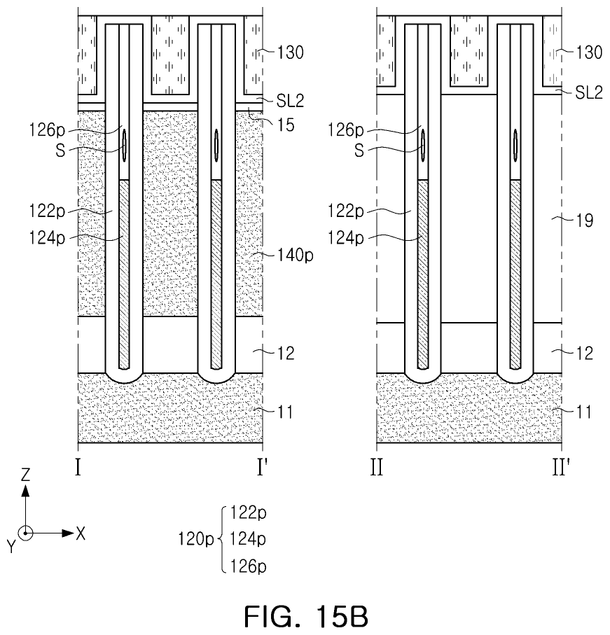

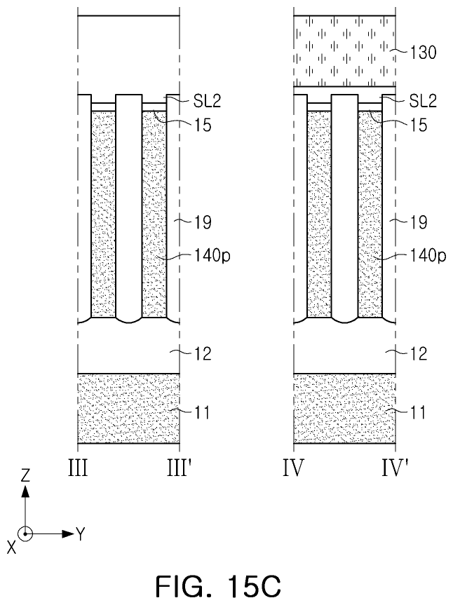

Referring to FIGS. 15A to 15C, gap-filling layers 130 may be formed between the first preliminary gate structures 120p (S120 of FIG. 9). A gap-filling material layer may be deposited on the second sacrificial layer SL2, and a planarization process may be performed to expose the second sacrificial layer SL2, thereby forming the gap-filling layers 130. The gap-filling layers 130 may extend in the Y-direction, and may be spaced apart from each other in the X-direction.

The gap-filling layers 130 may include a material having etch selectivity with respect to the second sacrificial layer SL2. In an example embodiment, the gap-filling layers 130 may include polysilicon, a metal, a conductive metal nitride, or combinations thereof. For example, the gap-filling layers 130 may include polysilicon.

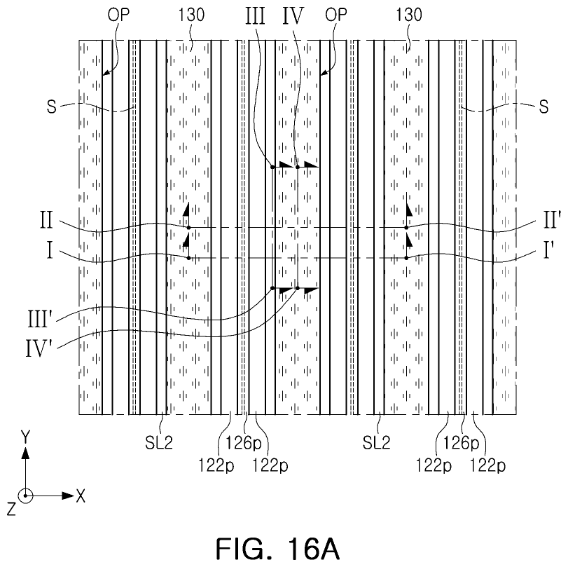

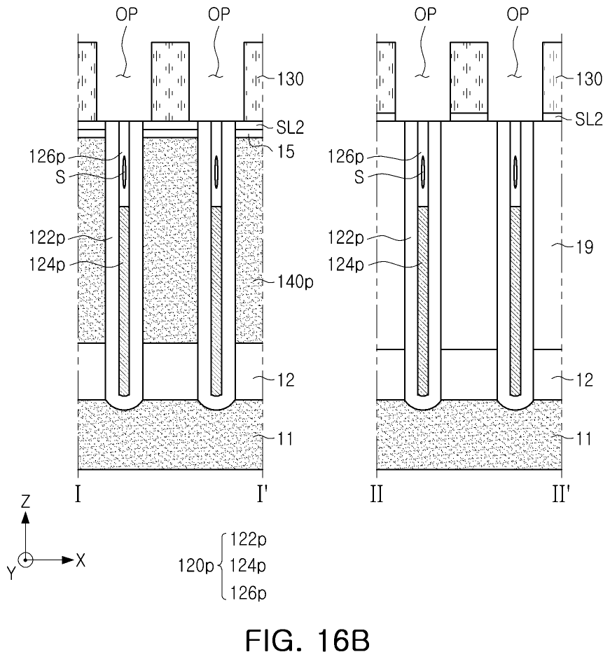

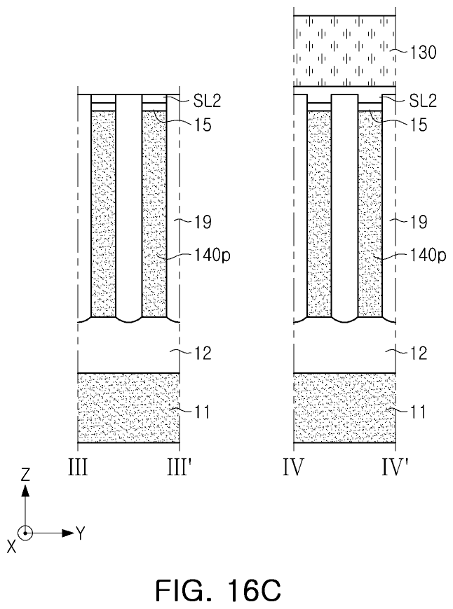

Referring to FIGS. 16A to 16C, upper portions of the first preliminary gate structures 120p may be etched to form an opening OP between the gap-filling layers 130 (S130 of FIG. 9). For example, the second sacrificial layer SL2, the dielectric material layer 122p, and the preliminary capping layer 126p may be partially etched using an etch-back process to form openings OP. The openings OP may expose side surfaces of the gap-filling layers 130. In FIG. 16B, it is illustrated that upper surfaces of the dielectric material layer 122p and the preliminary capping layer 126p after etching is performed are coplanar with an upper surface of the interlayer insulating layer 19, but the present invention is not limited thereto. In an example embodiment, the upper surfaces of the dielectric material layer 122p and the preliminary capping layer 126p after etching is performed may be disposed on a level, higher than that of the upper surface of the interlayer insulating layer 19.

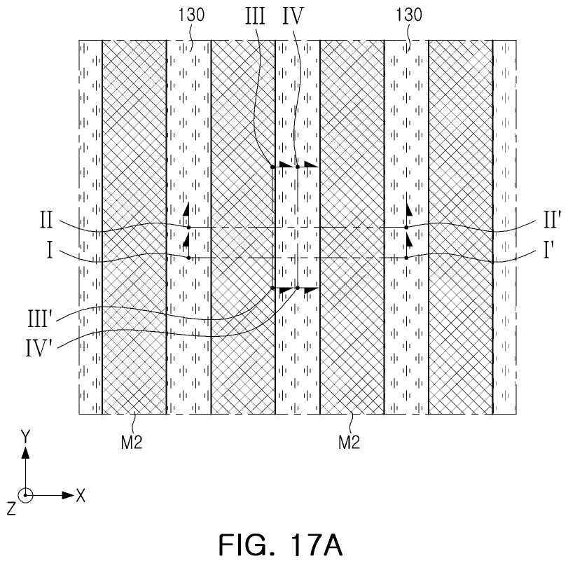

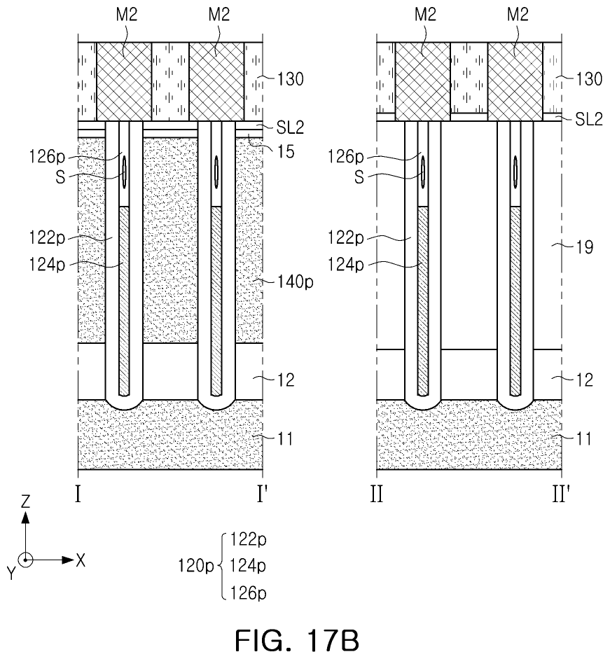

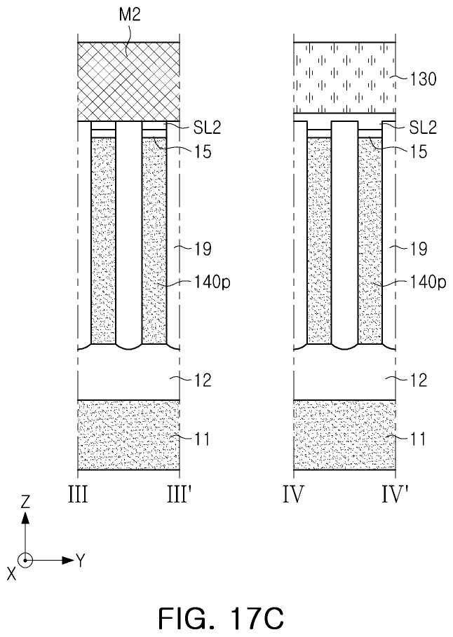

Referring to FIGS. 17A to 17C, a second mask layer M2, filling the opening OP, may be formed (S140 of FIG. 9). For example, the second mask layers M2 may be disposed on the first preliminary gate structures 120p. The second mask layers M2 may extend in the Y-direction along the first preliminary gate structures 120p, and may be spaced apart from each other in the X-direction. A horizontal width of each of the second mask layers M2 in the X-direction may be greater than a horizontal width of each of the first preliminary gate structures 120p in the X-direction.

The second mask layer M2 may include a material having etch selectivity with respect to the interlayer insulating layer 19 and the preliminary active pattern 140p. In an example embodiment, the second mask layer M2 may include polysilicon, a metal, a conductive metal nitride, or combinations thereof.

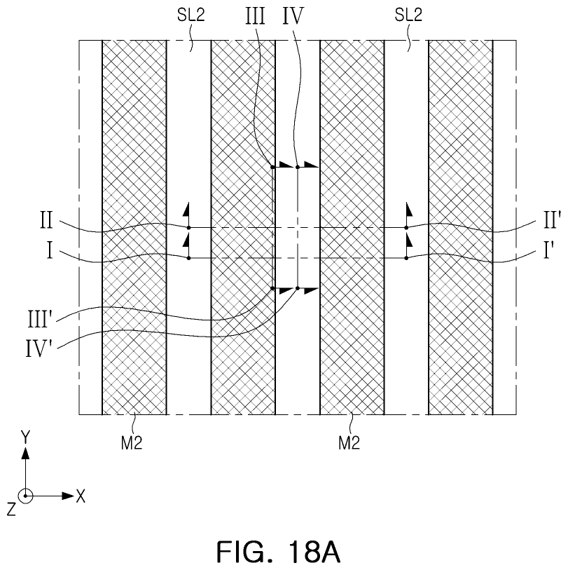

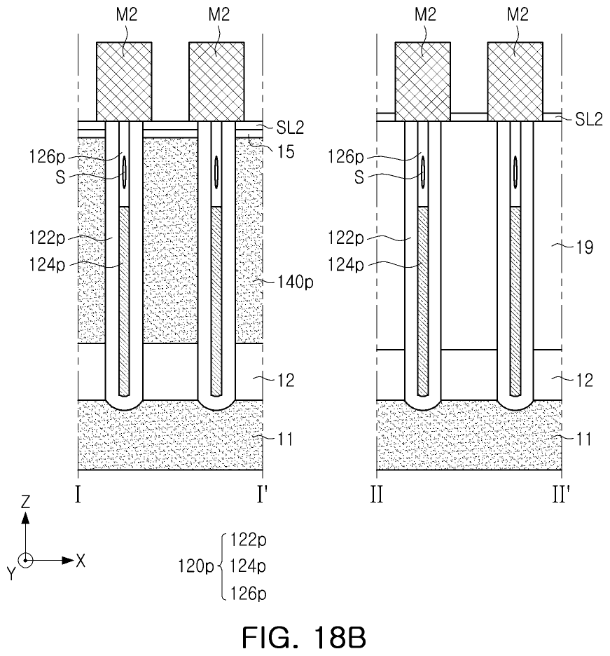

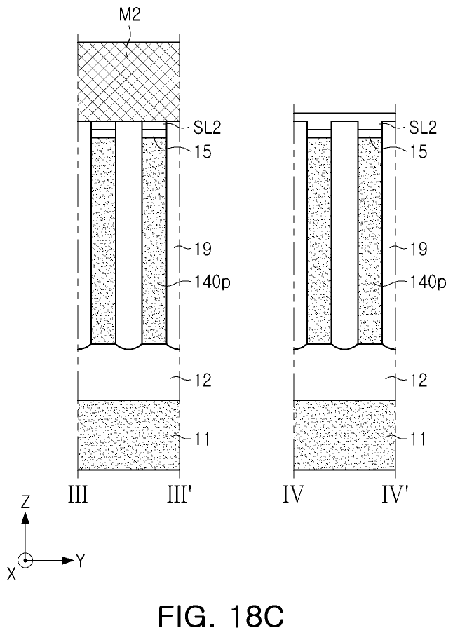

Referring to FIGS. 18A to 18C, the gap-filling layers 130 may be removed, and the second sacrificial layer SL2 may be exposed. The second sacrificial layer SL2 may include a material having etch selectivity with respect to the gap-filling layers 130, such that the second sacrificial layer SL2 may not be etched, and the gap-filling layers 130 may be selectively removed.

Referring to FIGS. 19A to 19C, active patterns 140 may be formed by etching the preliminary active patterns 140p using the second mask layer M2 as an etching mask (S150 of FIG. 9). For example, the preliminary active patterns 140p, extending in the X-direction, may be etched to form the active patterns 140 spaced apart from each other in the X-direction. As illustrated in FIG. 1A, in a plan view, the active patterns 140 may have a bar shape extending in the Y-direction, and may be spaced apart from each other in the X-direction and the Y-direction. In an embodiment, the active patterns 140 spaced apart from each other in the X-direction are formed after the active patterns 140 (e.g., the preliminary active patterns 140p of FIG. 11C) spaced apart from each other in the Y-direction are formed. The active patterns 140, the interlayer insulating layers 19, and the intermediate layer 12 may define gate trenches T3. For example, the gate trenches T3 may extend in the Y-direction between the first preliminary gate structures 120p, and may be spaced apart from each other in the X-direction. The gate trenches T3 may expose side surfaces of the active patterns 140 and the interlayer insulating layers 19, and an upper surface of the intermediate layer 12.

The interlayer insulating layer 19 may also be etched using the etching process. A horizontal width of each of the second mask layers M2 in the X-direction may be greater than a horizontal width of each of the first preliminary gate structures 120p in the X-direction, such that dielectric material layers 122p of the preliminary gate structures 120p may not be exposed. For example, the etched interlayer insulating layer 19 may extend in the Y-direction along the dielectric material layer 122p. It is illustrated that the intermediate layer 12 is not exposed on an etched portion of the interlayer insulating layer 19, but the present invention is not limited thereto.

The second mask layers M2 may be partially etched using the etching process. However, the second mask layers M2 may include a material having etch selectivity with respect to the interlayer insulating layer 19 and the preliminary active pattern 140p, such that the dielectric material layer 122p and the preliminary capping layer 126p may be protected, as compared to a case in which silicon oxide is used as an etching mask. Accordingly, the preliminary capping layer 126p may not be removed in the etching process to prevent the back gate electrode layer 124pfrom being exposed.

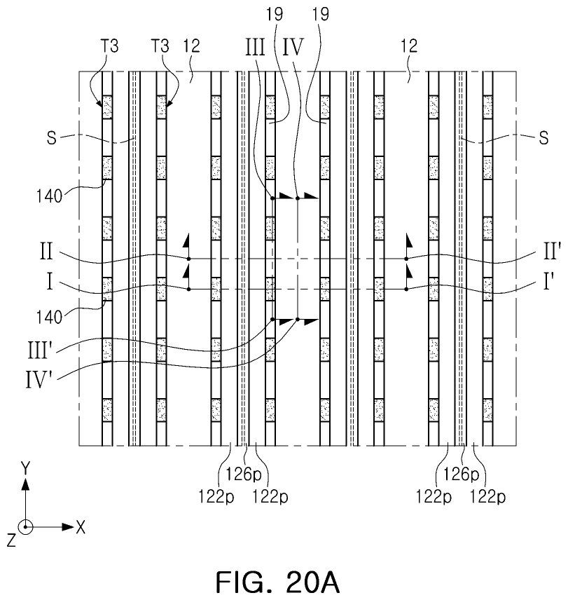

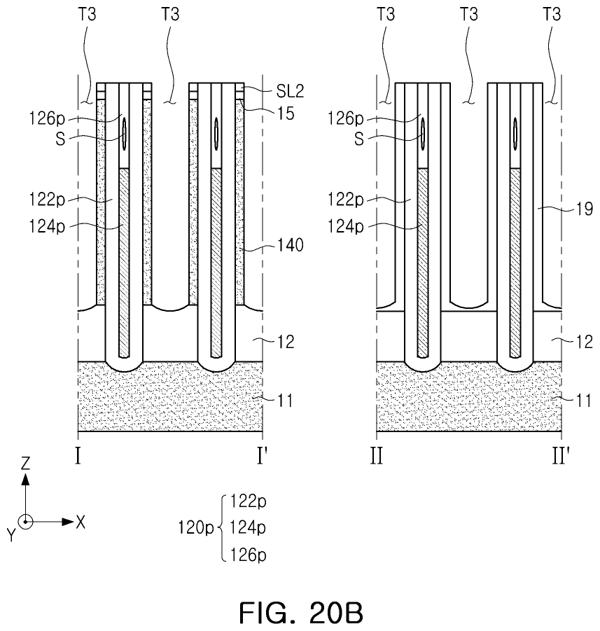

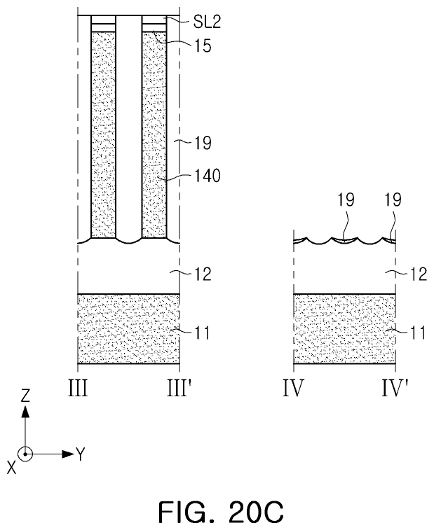

Referring to FIGS. 20A to 20C, the second mask layer M2 may be removed. The second mask layer M2 may include a material having etch selectivity with respect to the interlayer insulating layer 19 and the preliminary active pattern 140p, such that the interlayer insulating layer 19 and the active pattern 140 may not be etched.

Referring to FIGS. 21A to 21C, the interlayer insulating layer 19 may be etched. For example, the interlayer insulating layer 19 may be etched using a wet etching process or a chemical oxide removal (COR) method. In an example embodiment, the interlayer insulating layer 19 may not be entirely removed, and the interlayer insulating layer 19 may remain on a upper surface of the intermediate layer 12 and a side surface of the dielectric material layer 122p. In an example embodiment, the interlayer insulating layer 19 after etching is performed may be entirely removed. In an example embodiment, the interlayer insulating layer 19 after etching is performed may cover the dielectric material layer 122p, and a side surface of the dielectric material layer 122p may not be exposed.

The second sacrificial layer SL2 may be removed using the etching process, and an upper portion of the dielectric material layer 122p and an upper portion of the preliminary capping layer 126p may be etched.

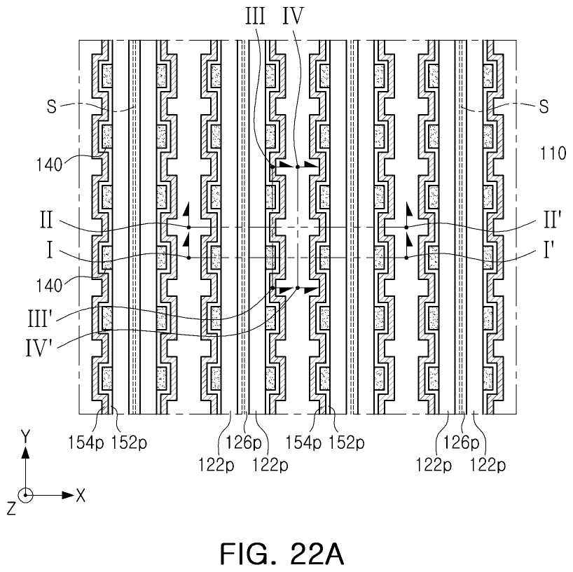

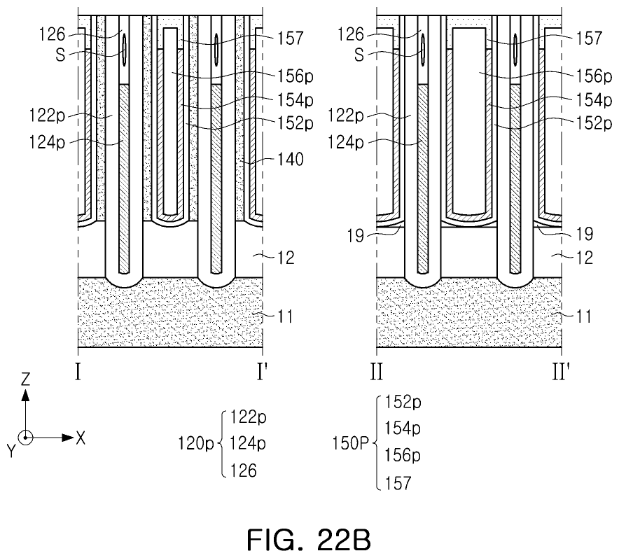

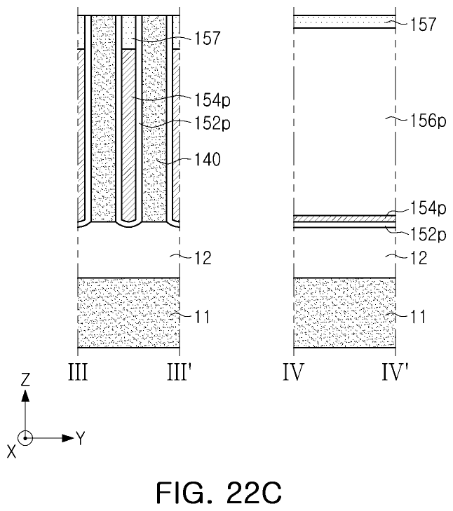

Referring to FIGS. 22A to 22C, second preliminary gate structures 150p may be formed between the active patterns 140 (S160 of FIG. 9). The dielectric material layer 152p may be formed to cover the gate trenches T3, and may cover upper surfaces of the first preliminary gate structures 120p, a side surface of the active pattern 140, and an upper surface of the intermediate layer 12.

After the conductive material layer and the insulating material layer are sequentially formed on the dielectric material layer 152p, the gate electrode layers 154p and the gap-filling insulating layers 156p may be formed by performing an etching process. The gate electrode layers 154p may be disposed on opposite sides of the first preliminary gate structures 120p, and may extend in the Y-direction. The gap-filling insulating layers 156p may be disposed on the gate electrode layers 154p, and may extend in the Y-direction.

After an insulating material is formed on the gate electrode layers 154p and the gap-filling insulating layers 156p, the insulating material may be etched to form first gate capping layers 157. The first gate capping layers 157 may cover upper surfaces of the gate electrode layers 154p and the gap-filling insulating layers 156p, and may be coplanar with the first preliminary gate structures 120p. The dielectric material layer 152p, the gate electrode layer 154p, the gap-filling insulating layer 156p, and the first gate capping layer 157 may form a second preliminary gate structure 150p. The second preliminary gate structures 150p and the first preliminary gate structures 120p may be alternately disposed in the X-direction, and may extend in the Y-direction.

The first buffer layers 15 may be removed before the dielectric material layer 152p is formed, and upper portions of the preliminary capping layers 126p may be etched to form upper capping layers 126.

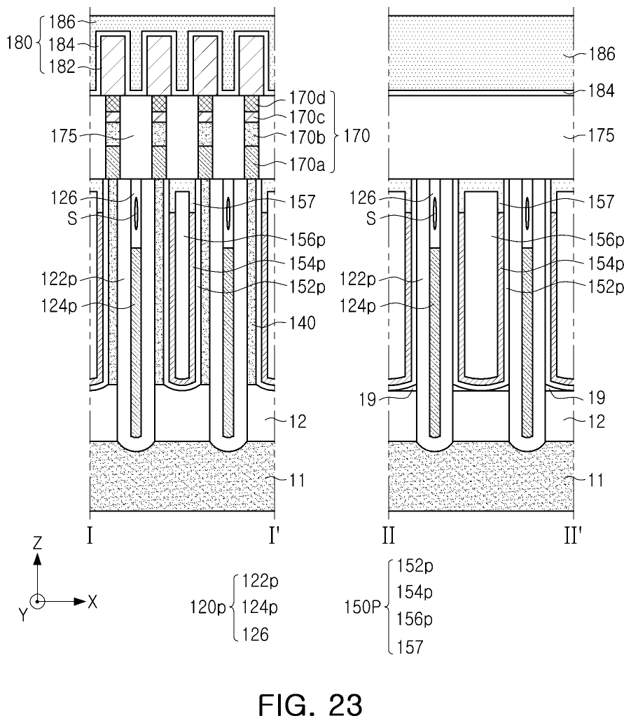

Referring to FIG. 23, a contact pattern 170 and an information storage structure 180 may be formed on one ends of the active patterns 140 (S170 of FIG. 9). The contact pattern 170 may include a first contact pattern 170a, a second contact pattern 170b, a third contact pattern 170c, and a fourth contact pattern 170d, sequentially stacked. The contact pattern 170 may be electrically connected to the active pattern 140.

In an example embodiment, after insulating patterns 175 are formed on the first preliminary gate structures 120p, the second preliminary gate structures 150p, and the active patterns 140, contact patterns 170 may be formed between the insulating patterns 175. The insulating patterns 175 may electrically insulate the contact patterns 170 from each other.

The information storage structure 180, including first electrodes 182, a dielectric layer 184, and a second electrode 186, may be formed on the contact patterns 170. The first electrodes 182 may be in contact with the fourth contact patterns 170d of the contact patterns 170.

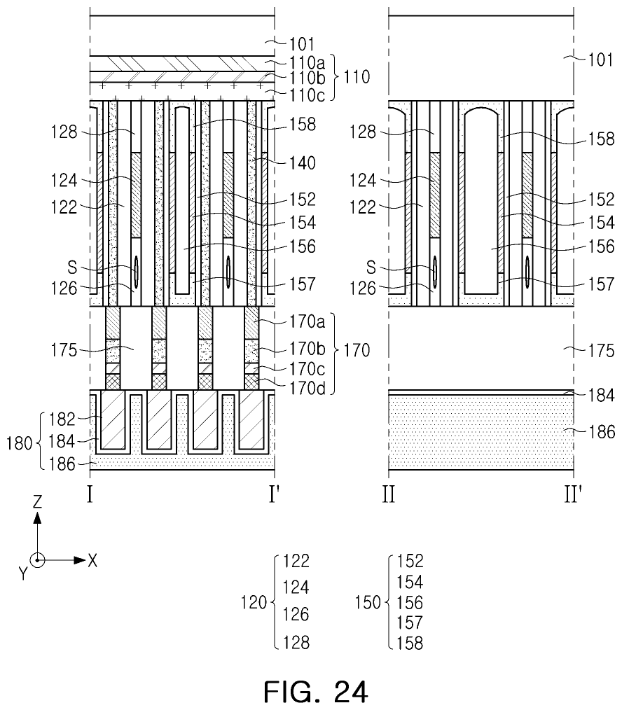

Referring to FIG. 24, the back gate electrode layers 124p of the first preliminary gate structures 120p may be etched back and filled with an insulating material to form the back gate structures 120.

For example, a result structure of FIG. 23 may be inverted such that the information storage structure 180 faces a lower portion of the lower substrate 11, and the lower substrate 11 and the intermediate layer 12 may be removed. The intermediate layer 12 may be removed to expose dielectric material layers 122p of the first preliminary gate structures 120p. The exposed dielectric material layers 122p may be etched to form back gate dielectric layers 122. Thereafter, the back gate electrode layers 124p may be etched back to form the back gate electrodes 124. The back gate electrodes 124 may be filled with an insulating material to form lower capping layers 128. The back gate dielectric layer 122, the back gate electrode 124, the upper capping layer 126, and the lower capping layer 128 may form a back gate structure 120.

The gate electrode layers 154p of the second preliminary gate structures 150p may be etched back and filled with an insulating material to form word line structures 150. For example, the intermediate layer 12 may be removed to expose dielectric material layers 152p of the second preliminary gate structures 150p. The exposed dielectric material layers 152p may be etched to form gate dielectric layers 152. Thereafter, the gate electrode layers 154p may be etched back to form word lines 154. When the word lines 154 are formed, the gap-filling insulating layer 156p may be partially etched to form a gap-filling insulating layer 156. The word lines 154 may be filled with an insulating material to form second gate capping layers 158. The gate dielectric layer 152, the word line 154, the gap-filling insulating layer 156, the first gate capping layer 157, and the second gate capping layer 158 may form a word line structure 150.

A lower insulating layer 101 and bit line structures 110 may be formed on the other ends of the active patterns 140 (S180), such that a semiconductor device 100 may be manufactured. The bit line structure 110 may include a third conductive pattern 110c, a second conductive pattern 110b, and a first conductive pattern 110a, sequentially stacked on the active patterns 140.

In an example embodiment, a peripheral circuit structure, including peripheral circuit elements electrically connected to at least one of the bit line structures 110, may be disposed on the lower insulating layer 101. In an example embodiment, the peripheral circuit structure may be disposed on the information storage structure 180 after the information storage structure 180 is formed.

In an example embodiment, a cleaning process may be further performed before the bit line structure 110 is formed. The cleaning process may remove an oxide film formed on the active patterns 140. Using the cleaning process, the back gate dielectric layer 122 and the gate dielectric layer 152 may be partially etched, and side surfaces of the active patterns 140 may be exposed. The exposed side surfaces of the active patterns 140 may be in contact with the bit line structure 110.

According to a semiconductor device manufacturing method of the present inventive concept, as illustrated in FIGS. 11A to 11C, a preliminary substrate 13 may be first etched in the X-direction. For example, the preliminary substrate 13 may be etched to form preliminary active patterns 140p extending in the X-direction, the preliminary active patterns 140p spaced apart from each other in the Y-direction. Thereafter, an interlayer insulating layer 19 may be formed to cover the preliminary active patterns 140p, and then the preliminary active patterns 140p may be etched in the Y-direction, as illustrated in FIGS. 19A to 19C. For example, the preliminary active patterns 140p may be etched to form active patterns 140 spaced apart from each other in the X-direction and the Y-direction.

When the preliminary substrate 13 is etched simultaneously in the X-direction and the Y-direction, an edge portion of the active pattern 140, illustrated in FIG. 1B, may be excessively etched. However, according to the semiconductor device manufacturing method of the present inventive concept, the preliminary substrate 13 may not be etched simultaneously in the X-direction and the Y-direction, and in the etching process of FIGS. 19A to 19C, a third side surface 140_S3 and a fourth side surface 140_S4 of the active pattern 140 may be covered by an interlayer insulating layer 19 (see FIG. 2), thereby preventing the active pattern 140 from being excessively etched. Accordingly, etching of the edge portion of the active pattern 140 may be prevented or reduced.

The etching process of FIGS. 19A to 19C may be performed using the second mask layer M2 as an etching mask. The second mask layer M2 may include a material having etch selectivity with respect to both the preliminary active pattern 140p and the interlayer insulating layer 19, such that the preliminary capping layer 126p and the dielectric material layer 122p may be protected by the second mask layer M2 in the etching process. Accordingly, the back gate electrode layer 124p may be prevented from being exposed in the etching process, and the active pattern 140 may be implemented even when a relatively shallow back gate trench T1 is formed, thereby simplifying the process. In addition, the second mask layer M2 may include a material having etch selectivity with respect to both the preliminary active pattern 140p and the interlayer insulating layer 19, such that the active pattern 140 may be implemented to have a finer pattern, as compared to a case in which the etching process is performed using a spacer including silicon oxide as an etch mask.

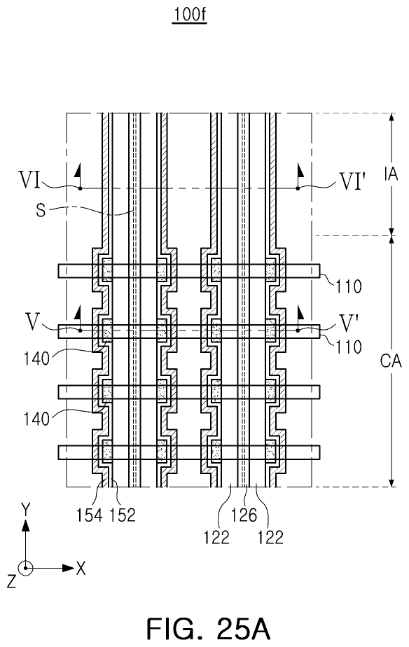

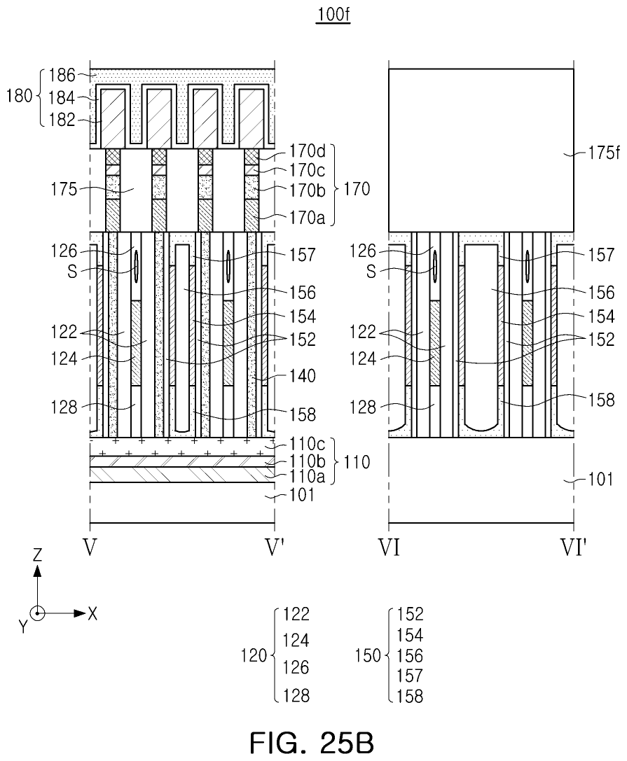

FIG. 25A is a plan view of a semiconductor device according to an example embodiment. FIG. 25B is vertical cross-sectional views of the semiconductor device illustrated in FIG. 25A, taken along line V-V′ and line VI-VI′ according to example embodiments.

Referring to FIGS. 25A and 25B, a semiconductor device 100f may include a cell array region CA and an interface region IA. The interface region IA may be disposed to surround the cell array region CA, and the interface region IA may be disposed between the cell array regions CA. The cell array region CA may refer to a region in which a memory cell of a DRAM device is disposed, for example, to a region in which a vertical channel transistor described with reference to FIGS. 1A and 2 is disposed.

The semiconductor device 100f may include contact plugs electrically connected to at least one of the back gate electrode 124 and the word line 154 in the interface region IA.

The back gate structure 120 and the word line structure 150 may extend from the cell array region CA to the interface region IA. For example, back gate dielectric layer 122, the back gate electrode 124, the upper capping layer 126, and the lower capping layer 128 of the back gate structure 120, and the gate dielectric layer 152, the word line 154, the gap-filling insulating layer 156, the first gate capping layer 157, and the second gate capping layer 158 of the word line structure 150 may extend from the cell array region CA to the interface region IA in the Y-direction. The active pattern 140 may be disposed in the cell array region CA, but may not be disposed in the interface region IA. For example, in the interface region IA, the gate dielectric layer 152 may be in contact with a side surface of the back gate dielectric layer 122, and may extend in the Y-direction along the side surface of the back gate dielectric layer 122. The contact pattern 170 and the information storage structure 180 may not be disposed in the interface region IA, and an insulating layer 175f may be disposed on the back gate structure 120 and the word line structure 150.

In an example embodiment, a seam S, formed in the upper capping layer 126 of the back gate structure 120, may continuously extend from the cell array region CA to the interface region IA.

In an example embodiment, the back gate electrode 124 may be disposed on the same level in the cell array region CA and the interface region IA. For example, a lower surface and an upper surface of the back gate electrode 124 in the cell array region CA may be disposed on levels the same as those of a lower surface and an upper surface of the back gate electrode 124 in the interface region IA, respectively. In an example embodiment, the word line 154 may be disposed on the same level in the cell array region CA and the interface region IA. For example, a lower surface and an upper surface of the word line 154 in the cell array region CA may be disposed on levels the same as those of a lower surface and an upper surface of the word line 154 in the interface region IA, respectively.

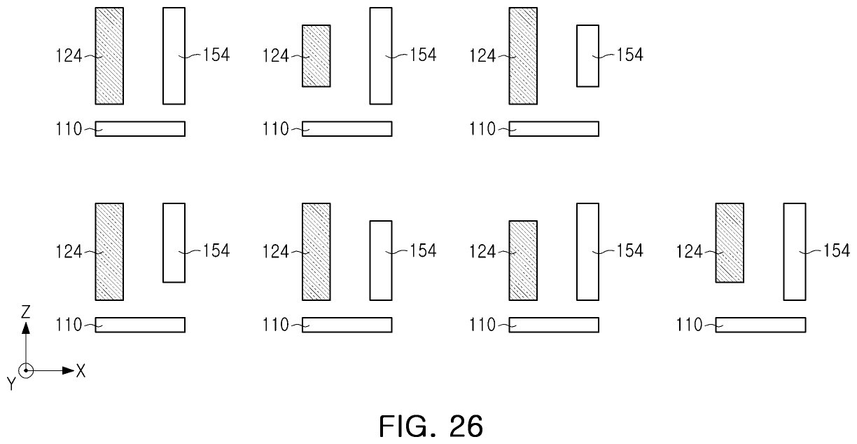

FIG. 26 is schematic cross-sectional views of an arrangement structure of a back gate electrode and a word line included in a semiconductor device according to example embodiments.

Referring to FIG. 26, an upper surface of a back gate electrode 124 and an upper surface of a word line 154 may be disposed on the same level or different levels. A lower surface of the back gate electrode 124 and a lower surface of the word line 154 may be disposed on the same level or different levels. Here, the lower surface of the back gate electrode 124 and the lower surface of the word line 154 may refer to a surface of the back gate electrode 124 and a surface of the word line 154 opposing the bit line structure 110, respectively. The upper surface of the back gate electrode 124 and the upper surface of the word line 154 may be surfaces opposing the lower surface of the back gate electrode 124 and the lower surface of the word line 154, respectively. A vertical length of the back gate electrode 124 in a Z-direction may be the same or different from a vertical length of the word line 154 in the Z-direction.

According to example embodiments of the present inventive concept, an active pattern may not be patterned using a single process but may be formed using a plurality of etching processes, thereby preventing the active pattern from being excessively etched.

While example embodiments have been shown and described above, it will be apparent to those skilled in the art that modifications and variations could be made without departing from the scope of the present invention as defined by the appended claims.

What is claimed is:

1. A semiconductor device comprising:
a bit line structure;
a back gate structure extending on the bit line structure in a first horizontal direction, the back gate structure including a back gate electrode and an upper capping layer on the back gate electrode;
a word line structure disposed on the bit line structure, the word line structure including a word line and a gate dielectric layer covering a side surface of the word line;
an active pattern disposed on the bit line structure, the active pattern extending in a vertical direction between the back gate structure and the word line structure; and
a contact pattern on the active pattern,
wherein the upper capping layer includes a seam extending in the first horizontal direction.

2. The semiconductor device of claim 1, wherein, in a plan view:
the active pattern includes a first edge portion adjacent to the back gate structure, and a second edge portion adjacent to the word line structure, and
at least one of the first edge portion and the second edge portion is rounded.

3. The semiconductor device of claim 2, wherein both the first edge portion and the second edge portion are rounded.

4. The semiconductor device of claim 3, wherein a radius of curvature of the first edge portion is different from a radius of curvature of the second edge portion.

5. The semiconductor device of claim 1, wherein the back gate structure further includes a back gate dielectric layer in contact with a portion of the gate dielectric layer of the word line structure, and
wherein, in a plan view:
the active pattern has a first side surface adjacent to the back gate structure, a second side surface opposite to the first side surface, and a third side surface and a fourth side surface spaced apart from each other in the first horizontal direction,
the first side surface is in contact with the back gate dielectric layer of the back gate structure, and
the second side surface, the third side surface, and the fourth side surface are in contact with the gate dielectric layer of the word line structure.

6. The semiconductor device of claim 5, wherein at least a portion of the third side surface and at least a portion of the fourth side surface overlap the word line in the first horizontal direction.

7. The semiconductor device of claim 5, wherein the active pattern has curved surfaces in at least one of first portions between the first side surface and the third side surface and between the first side surface and the fourth side surface, and second portions between the second side surface and the third side surface and between the second side surface and the fourth side surface.

8. The semiconductor device of claim 1, wherein, in a plan view:
the active pattern includes a first side surface adjacent to the back gate structure, a second side surface opposite to the first side surface, and a third side surface and a fourth side surface spaced apart from each other in the first horizontal direction,
the first side surface has a first width in the first horizontal direction, and
the first width is less than a maximum width of the active pattern in the first horizontal direction.

9. The semiconductor device of claim 8, wherein at least one of the third and fourth side surfaces has a second width in a second horizontal direction, intersecting the first horizontal direction, and
wherein the second width is less than a maximum width of the active pattern in the second horizontal direction.

10. The semiconductor device of claim 1, further comprising:
a liner overlapping the active pattern in the first horizontal direction,
wherein the back gate structure further includes a back gate dielectric layer disposed between the back gate electrode and the active pattern, the back gate dielectric layer extending in the first horizontal direction, and
wherein the liner is in contact with the active pattern and the back gate dielectric layer.

11. The semiconductor device of claim 10, wherein the liner extends in the first horizontal direction between the back gate dielectric layer and the gate dielectric layer.

12. The semiconductor device of claim 10, wherein, in a plan view, a side surface of the liner has a curved surface.

13. The semiconductor device of claim 10, wherein a density of the liner is lower than a density of the back gate dielectric layer.

14. The semiconductor device of claim 10, wherein a maximum horizontal width of the liner in a second horizontal direction, intersecting the first horizontal direction, is less than a horizontal width of the active pattern in the second horizontal direction.

15. The semiconductor device of claim 10, wherein a side surface of the active pattern extending in a second horizontal direction, intersecting the first horizontal direction, is in contact with the liner and the gate dielectric layer.

16. A semiconductor device comprising:
a bit line structure on a cell array region;
a back gate structure extending from the cell array region to an interface region, on the bit line structure, the back gate structure including a back gate electrode and an upper capping layer on the back gate electrode;
a word line structure disposed on the bit line structure, the word line structure extending from the cell array region to the interface region, the word line structure including a word line and a gate dielectric layer covering a side surface of the word line;
an active pattern disposed on the bit line structure, on the cell array region, the active pattern extending in a vertical direction between the back gate structure and the word line structure; and
a contact pattern on the active pattern,
wherein the upper capping layer includes a seam extending from the cell array region to the interface region.

17. The semiconductor device of claim 16, wherein the back gate electrode continuously extends from the cell array region to the interface region.

18. The semiconductor device of claim 17, wherein an upper surface of the back gate electrode in the cell array region is disposed on a level, the same as that of an upper surface of the back gate electrode in the interface region.

19. The semiconductor device of claim 16, wherein the word line continuously extends from the cell array region to the interface region.

20. A semiconductor device comprising:
a bit line structure;
a back gate structure extending on the bit line structure in a first horizontal direction, the back gate structure including a back gate electrode and an upper capping layer on the back gate electrode;
a word line structure disposed on the bit line structure, the word line structure including a word line and a gate dielectric layer covering a side surface of the word line;
an active pattern disposed on the bit line structure, the active pattern extending in a vertical direction between the back gate structure and the word line structure;
a contact pattern on the active pattern; and
an information storage structure on the contact pattern,
wherein, in a plan view:
at least two side surfaces of the active pattern are in contact with the gate dielectric layer,
the upper capping layer includes a seam extending in the first horizontal direction, and
a lower end and an upper end of the seam are disposed between a lower surface and an upper surface of the upper capping layer.
